(19) United States
(12) Patent Application Publication
(10) Pub. No.: US 2026/0361324 A1
(43) Pub. Date: Nov. 12, 2026

(54) TECHNIQUES FOR COMMUNICATING HARQ FEEDBACK USING PRUNED HUFFMAN CODING

(71) Applicant: QUALCOMM Incorporated, San Diego, CA (US)

(72) Inventors: Ori SHENTAL, Marlboro, NJ (US); Mostafa KHOSHNEVISAN, San Diego, CA (US); Wei YANG, San Diego, CA (US); Junyi LI, Greentown, PA (US); Jing JIANG, San Diego, CA (US)

(21) Appl. No.: 19/201,763

(22) Filed: May 7, 2025

(51) Int. Cl. H03M 13/37; H03M 7/40

(52) U.S. Cl. CPC H03M 13/3761; H03M 7/40

(57) ABSTRACT

This disclosure provides methods, components, devices and systems for communicating hybrid automatic repeat request (HARQ) feedback using pruned Huffman coding. For example, a first wireless device may communicate, with a second wireless device, signaling that may indicate one or more conditions for a pruned compression coding configuration. In accordance with the one or more conditions for the pruned compression coding configuration, one or more nodes of a full binary coding tree may be replaced with a plurality of equiprobable bits to generate a pruned binary coding tree. The first wireless device may may generate one or more codewords based on one or more feedback bits in accordance with the pruned binary coding tree. The first wireless device may transmit a feedback message to the second wireless device based on channel encoding the one or more codewords.

### TECHNICAL FIELD

This disclosure relates generally to wireless communication, and more specifically to systems, devices, methods, and techniques associated with communicating hybrid automatic repeat request (HARQ) feedback using pruned Huffman coding.

### DESCRIPTION OF THE RELATED TECHNOLOGY

Communication systems are deployed to provide communication services such as voice, video, packet data, messaging, or broadcast, among others. A communication system may include a wireless communication network (such as a radio access network (RAN)) that supports communication between wireless communication devices such as network entities (such as base stations), client devices (such as one or more user equipments (UEs)), and others. Such devices may communicate with one another using a variety of protocols (such as radio access technologies (RATs)), including those of cellular-based systems such as fourth generation (4G) systems (such as Long Term Evolution (LTE) systems), fifth generation (5G) systems (such as 5G New Radio (5G-NR) systems), and sixth generation (6G) systems. A wireless communication network may support communication by implementing system resources (such as frequency resources, time resources, spatial resources) in accordance with a wireless communication protocol.

### SUMMARY

The systems, methods, and devices of this disclosure each have several innovative aspects, no single one of which is solely responsible for the desirable attributes disclosed herein. The following is a summary of some non-limiting aspects of the disclosure:

A method for wireless communications by a first wireless device is described. The method may include communicating, with a second wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree, generating one or more codewords based on one or more feedback bits in accordance with the pruned binary coding tree, and transmitting a feedback message to the second wireless device based on channel encoding the one or more codewords.

A first wireless device for wireless communications is described. The first wireless device may include a processing system that includes processor circuitry and memory circuitry that stores code. The processing system may be configured to cause the first wireless device to communicate, with a second wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree, generate one or more codewords based on one or more feedback bits in accordance with the pruned binary coding tree, and transmit a feedback message to the second wireless device based on channel encoding the one or more codewords.

Another first wireless device for wireless communications is described. The first wireless device may include means for communicating, with a second wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree, means for generating one or more codewords based on one or more feedback bits in accordance with the pruned binary coding tree, and means for transmitting a feedback message to the second wireless device based on channel encoding the one or more codewords.

A non-transitory computer-readable medium storing code for wireless communications is described. The code may include instructions executable by one or more processors to communicate, with a second wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree, generate one or more codewords based on one or more feedback bits in accordance with the pruned binary coding tree, and transmit a feedback message to the second wireless device based on channel encoding the one or more codewords.

In some examples of the method, first wireless devices, and non-transitory computer-readable medium described herein, the one or more conditions for the pruned compression coding configuration include a pruned binary coding tree depth, a maximum codeword length, a quantity of codeword length groups, a quantity of channel encoding steps, a quantity of channel decoding steps, or any combination thereof.

In some examples of the method, first wireless devices, and non-transitory computer-readable medium described herein, in accordance with the one or more conditions for the pruned compression coding configuration, a first maximum codeword length associated with the pruned binary coding tree may be shorter than a second maximum codeword length associated with the full binary coding tree and in accordance with the one or more conditions for the pruned compression coding configuration, a first quantity of codeword length groups associated with the pruned binary coding tree may be less than a second quantity of codeword length groups associated with the full binary coding tree.

Some examples of the method, first wireless devices, and non-transitory computer-readable medium described herein may further include operations, features, means, or instructions for generating the full binary coding tree based on the one or more feedback bits including independent and identically distributed (IID) bits, and where the full binary coding tree may be generated in accordance with a probability associated with each bit of the one or more feedback bits and generating the pruned binary coding tree based on the full binary coding tree and in accordance with the one or more conditions for the pruned compression coding configuration.

Some examples of the method, first wireless devices, and non-transitory computer-readable medium described herein may further include operations, features, means, or instructions for generating the full binary coding tree based on the one or more feedback bits including correlated feedback bits, and where the full binary coding tree may be generated in accordance with a probability associated with each bit of the one or more feedback bits and in accordance with a correlation factor associated with the one or more feedback bits and generating the pruned binary coding tree based on the full binary coding tree and in accordance with the one or more conditions for the pruned compression coding configuration.

A method for wireless communications by a second wireless device is described. The method may include communicating, with a first wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree, receiving a feedback message including one or more encoded codewords, and decoding the one or more encoded codewords based on the pruned binary coding tree to obtain one or more feedback bits of the feedback message.

A second wireless device for wireless communications is described. The second wireless device may include a processing system that includes processor circuitry and memory circuitry that stores code. The processing system may be configured to cause the second wireless device to communicate, with a first wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree, receive a feedback message including one or more encoded codewords, decode the one or more encoded codewords based on the pruned binary coding tree to obtain one or more feedback bits of the feedback message.

Another second wireless device for wireless communications is described. The second wireless device may include means for communicating, with a first wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree, means for receiving a feedback message including one or more encoded codewords, means for decoding the one or more encoded codewords based on the pruned binary coding tree to obtain one or more feedback bits of the feedback message.

A non-transitory computer-readable medium storing code for wireless communications is described. The code may include instructions executable by one or more processors to communicate, with a first wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree, receive a feedback message including one or more encoded codewords, decode the one or more encoded codewords based on the pruned binary coding tree to obtain one or more feedback bits of the feedback message.

In some examples of the method, second wireless devices, and non-transitory computer-readable medium described herein, the one or more conditions for the pruned compression coding configuration include a pruned binary coding tree depth, a maximum codeword length, a quantity of codeword length groups, a quantity of channel encoding steps, a quantity of channel decoding steps, or any combination thereof.

In some examples of the method, second wireless devices, and non-transitory computer-readable medium described herein, in accordance with the one or more conditions for the pruned compression coding configuration, a first maximum codeword length associated with the pruned binary coding tree may be shorter than a second maximum codeword length associated with the full binary coding tree and in accordance with the one or more conditions for the pruned compression coding configuration, a first quantity of codeword length groups associated with the pruned binary coding tree may be less than a second quantity of codeword length groups associated with the full binary coding tree.

Some examples of the method, second wireless devices, and non-transitory computer-readable medium described herein may further include operations, features, means, or instructions for generating the full binary coding tree based on the one or more feedback bits including IID bits, and where the full binary coding tree may be generated in accordance with a probability associated with each bit of the one or more feedback bits and generating the pruned binary coding tree based on the full binary coding tree and in accordance with the one or more conditions for the pruned compression coding configuration.

Some examples of the method, second wireless devices, and non-transitory computer-readable medium described herein may further include operations, features, means, or instructions for generating the full binary coding tree based on the one or more feedback bits including correlated feedback bits, and where the full binary coding tree may be generated in accordance with a probability associated with each bit of the one or more feedback bits and in accordance with a correlation factor associated with the one or more feedback bits and generating the pruned binary coding tree based on the full binary coding tree and in accordance with the one or more conditions for the pruned compression coding configuration.

### BRIEF DESCRIPTION OF THE DRAWINGS

FIG. 1 shows an example of a wireless communication system.

FIG. 2 shows an example of a signaling configuration that supports techniques for communicating hybrid automatic repeat request (HARQ) feedback using pruned Huffman coding.

FIGS. 3 and 4 show example of Huffman tree diagrams that support techniques for communicating HARQ feedback using pruned Huffman coding.

FIG. 5 shows an example of a process flow that supports techniques for communicating HARQ feedback using pruned Huffman coding.

FIG. 6 shows a block diagram of a processing system that supports techniques for communicating HARQ feedback using pruned Huffman coding.

FIG. 7 shows a diagram of a system including a UE that supports techniques for communicating HARQ feedback using pruned Huffman coding in accordance with one or more aspects of the present disclosure.

FIG. 8 shows a diagram of a system including a network entity that supports techniques for communicating HARQ feedback using pruned Huffman coding in accordance with one or more aspects of the present disclosure.

FIGS. 9 through 12 show flowcharts illustrating methods that support techniques for communicating HARQ feedback using pruned Huffman coding.

Details of aspects and advantages of the subject matter in this disclosure are set forth in the drawings and accompanying descriptions. Like reference numbers and designations in the various drawings indicate like elements.

### DETAILED DESCRIPTION

A communication system may include a radio access network (RAN) that supports wireless communication. Communication of a RAN may be performed in accordance with one or more radio access technologies (RATs), including 4G, 5G, or 6G, among others, including technologies not explicitly mentioned herein. A RAT may employ access technologies (such as multiplexing technologies) including code division multiple access (CDMA), time division multiple access (TDMA), frequency division multiple access (FDMA), orthogonal FDMA (OFDMA), single-carrier FDMA (SC-FDMA), time division synchronous code division multiple access (TD-SCDMA), or discrete Fourier transform spread orthogonal frequency division multiplexing (DFT-S-OFDM), among others. A RAT may support one or more service types, including machine type communication (MTC), massive MTC (mMTC), Internet of Things (IoT), narrowband IoT (NB-IoT), reduced capability (RedCap), enhanced mobile broadband (eMBB), ultra-reliable low-latency communication (URLLC), or public safety, among others.

To support these and other target verticals, a communication system (such as a RAN) may be designed to implement one or more of a modularized functional infrastructure, a disaggregated and service-based network architecture, network function virtualization, network slicing, multi-access edge computing, spatial processing or multipath techniques, IoT or RedCap device connectivity and management, industrial connectivity, licensed and unlicensed spectrum access, sidelink or other device-to-device (D2D) direct communication (such as vehicle-to-everything (V2X)), frequency spectrum expansion, overlapping spectrum use, small cell deployments, non-terrestrial network (NTN) deployments, device aggregation, advanced duplex communication (such as sub-band full-duplex (SBFD)), multiple-subscriber implementations, high-precision positioning, radio frequency (RF) sensing, network energy savings (NES), low-power signaling and radios, or artificial intelligence or machine learning (AI/ML), among other examples.

The foregoing and other technological improvements may support use cases such as voice calls, messaging, data transfer, streaming, wireless data centers, extended reality (XR) and metaverse applications, vehicle connectivity, holographic and mixed reality communication, autonomous and collaborative robots, sensing networks, gesture monitoring, human-brain interfacing, digital twin applications, asset management, and universal coverage using non-terrestrial or aerial platforms, among other examples. As the demand for connectivity continues to increase, further improvements may be implemented, and other RATs, including 6G and beyond, may be introduced to enable new applications and use cases. The systems, methods, and devices described herein may enable one or more of the foregoing technologies or new technologies or support one or more of the foregoing use cases or new use cases.

In some wireless communications systems, devices, such as wireless devices, may provide feedback (e.g., hybrid automatic repeat request (HARQ) feedback) for message transmissions and retransmissions using acknowledgment/negative acknowledgment (ACK/NACK) messages. In some implementations, an “ACK” and a “NACK” may be represented as single bits. For example, a bit of “1” may represent an ACK and a bit of “0” may represent a NACK. In some cases, multiple ACK/NACK bits may be sent in one feedback message. In some examples, the feedback messages may be encoded with a linear code without any compression, which may be inefficient and associated with high overhead. In other examples, a two-part HARQ-ACK coding scheme may be introduced, which may compress the ACK/NACK bits and limit a source codeword length variability. However, the two-part HARQ-ACK coding scheme may also be inefficient, such as due to partitioning challenges.

In some implementations, there may be some probability associated with sending ACK or NACK bits. For example, it may be more probable to send an ACK bit. As a result, the sequence of ACK/NACK bits forming the feedback message may be probabilistic. For example, receiving a series of ACK bits, (e.g., ‘11111’) may be more probable than receiving a series of ACK bits with one NACK bit (e.g., ‘10111’). In some examples, messages may be encoded based on probability to minimize a quantity of bits used for more probable bit sequences, which may be known as compression coding. That is, compression coding is the process of encoding information using fewer bits than the original representation, and may be performed to reduce storage space and transmission time. For example, a bit sequence with five bits may be “compressed” into four, three, two, or even one bit, thereby simplifying the transmission of the information.

One example of a compression coding configuration is Huffman coding. Huffman codes may be a lossless (e.g., optimal, minimal bits, high compression) source coding that may use series of bits to define different codewords (e.g., Huffman codewords) that represent possible combinations of the ACK/NACK sequences. The Huffman codewords may be assigned or mapped to the possible ACK/NACK sequences based on probability, such that fewer bits are used to encode more probable ACK/NACK sequences. For example, a sequence of all ACK bits (e.g., ‘11111’) may be encoded as a bit of ‘0’ using Huffman coding, as this may be the most probable sequence of ACK/NACK bits. This may reduce the length of the codeword for more probable ACK/NACK sequences. However, Huffman coding may result in highly variable codeword lengths. For example, because a sequence such as all NACK bits (e.g., ‘00000’) may be unlikely to occur, it may use many more bits than the most likely sequence (e.g., ‘11111’). Thus, the maximum codeword length may be long, resulting in high variability in length between possible codewords, as there may be many possible lengths of codewords. This variability may make subsequent channel encoding more complex and difficult to implement, among other challenges.

Aspects of the subject matter described in this disclosure relate to techniques to support a wireless device to implement pruned compression coding configurations (e.g., pruned Huffman coding configurations), which may replace low-probability, lengthy “nodes” in a binary coding tree (e.g., Huffman tree) with set quantities of equally probable (e.g., equiprobable) bits. For example, devices may communicate one or more conditions or rules for pruning a Huffman tree, such as limiting a Huffman tree depth, a threshold quantity of bits for a codeword, a threshold quantity of codeword length groups, a threshold quantity of steps for channel encoding or decoding, or any combination thereof. After determining some feedback bits, a wireless device may generate a Huffman tree and prune the Huffman tree according to the one or more conditions. By replacing one or more nodes of the Huffman tree with equiprobable bits, the codeword lengths may be reduced and the quantity of codeword length groups may be less variable. This may aid in channel encoding and decoding due to the lower codeword length variability. In some cases, this may result in less compression than using a full Huffman code (e.g., more bits, higher entropy), but may still be advantageous compared to other coding implementations, such as linear coding or two-part HARQ-ACK coding.

Particular aspects of the subject matter described in this disclosure can be implemented to realize one or more of the following potential advantages. In some examples, by implementing a pruned Huffman coding, the described techniques can be used to reduce processing and latency associated with channel encoding and decoding for variable codewords.

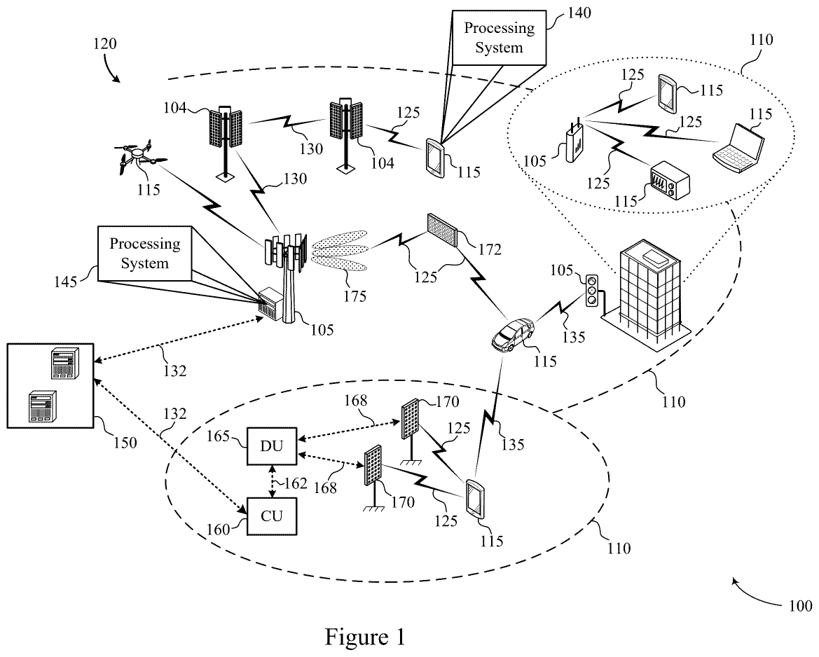

FIG. 1 shows an example of a wireless communication system 100. The wireless communication system 100 includes a core network 150 and a RAN 120 that support communication with one or more devices, such as UEs 115. A RAN 120 may include one or more network entities 105 configured to support wireless communication with the UEs 115.

The wireless communication system 100 may support communication among network entities 105 and UEs 115 in accordance with a layered protocol stack. For example, in a user plane, communication at a bearer layer, a Packet Data Convergence Protocol (PDCP) layer, or Service Data Adaption Protocol (SDAP) layer may be Internet Protocol (IP)-based. A Radio Link Control (RLC) layer may perform packet segmentation and reassembly to communicate via logical channels. A Medium Access Control (MAC) layer may perform priority handling and multiplexing of logical channels into transport channels. A MAC layer also may implement error detection techniques, error correction techniques, or retransmissions. In a control plane, a Radio Resource Control (RRC) layer may provide establishment, configuration, and maintenance of an RRC connection between UEs 115 and a network entity 105 or a core network 150, supporting radio bearers for user plane data. A Physical (PHY) layer may map transport channels to physical channels.

A core network 150 may support user authentication, access authorization, tracking, IP connectivity, and other access, routing, or mobility functions (such as via network entities 105). A core network 150 may be a 5G core (5GC) or 6G core (6GC), and may include at least one control plane entity that manages access and mobility and at least one user plane entity that routes packets or interconnects to external networks (such as a serving gateway (S-GW), a Packet Data Network (PDN) gateway (P-GW), a user plane function (UPF)).

A network entity 105 may support wireless communication in accordance with one or more coverage areas 110, and may be referred to as a network element, a network node, a RAN node, or network equipment, among other nomenclature. One or more of the network entities 105 may include or may be referred to as a base station. Depending on its capabilities, a base station may be referred to as a NodeB, an eNodeB (eNB), a next-generation NodeB or giga-NodeB (either of which may be referred to as a gNB), a 5G NB, a 6G NB, a next-generation eNB (ng-eNB), a Home NodeB, a Home eNodeB, or other suitable terminology. The wireless communication system 100 may include a heterogeneous network in which different types of network entities 105 support communication for one or more coverage areas 110 using the same or different RATs.

In some examples, a network entity 105 may be implemented in an aggregated (such as monolithic, standalone) architecture, which may utilize a protocol stack that is physically or logically integrated within one network entity 105 (such as a single physical RAN node). In some other examples, a network entity 105 may be implemented in a disaggregated architecture, which may utilize a protocol stack that is physically or logically distributed among multiple network entities 105, including in an integrated access and backhaul (IAB) network, an open RAN (O-RAN), or a virtualized RAN (vRAN). In a disaggregated architecture, a network entity 105 may include or be referred to as one or more of a central unit (CU) (such as CU 160), a distributed unit (DU) (such as DU 165), a radio unit (RU) (such as RU 170), or a combination thereof. The wireless communication system 100 may also implement a service-based architecture that provides a modular framework in which control plane functionality and common data repositories may be delivered through a set of interconnected network functions (NFs) that may access services of other NFs.

UEs 115 may be located in a coverage area 110 of one or more network entities 105, and may include or be referred to as an access terminal, a mobile station, a client device, or a subscriber unit. A UE 115 may be, include, or be coupled with a cellular phone, a wireless modem, a tablet device, a laptop computer, a wireless local loop (WLL) station, a camera, a medical or biometric device, a wearable device, a gaming device, an entertainment device, an XR device, a vehicular component or sensor, a smart meter or sensor, industrial manufacturing equipment, a Global Positioning System (GPS) or other positioning device, a robot or other device implementing artificial intelligence, a UE function of a network node, or any other wireless communication device or function that may communicate using a wireless medium.

The wireless communication system 100 may support various types of communication links among devices. For example, wireless communication between a network entity 105 and a UE 115 may be supported using one or more of a communication link 125 (such as a Uu interface), which may include downlink communication from a network entity 105 to a UE 115, uplink communication from a UE 115 to a network entity 105, or both. Direct wireless communication between UEs 115 may be supported using a communication link 135 (such as a device-to-device (D2D) communication link, a sidelink, a PC5 interface).

Communication between a network entity 105 and a core network 150 may be supported using a backhaul link 132 (such as an S1, N2, N3, NG, or other interface). In some implementations, communication between network entities 105 may be supported using a backhaul link 132 (such as an X2, Xn, or other interface) either directly (such as directly between network entities 105) or indirectly (such as via a core network 150). In some implementations (such as in a disaggregated architecture), communication between a CU 160 and a DU 165 may be supported using a midhaul link 162, and communication between a DU 165 and an RU may be supported using a fronthaul link 168. A backhaul link 132, a midhaul link 162, a fronthaul link 168, or any combination thereof may be or include one or more wired links (such as an electrical link, an optical fiber link) or one or more wireless links (such as a radio link, a wireless optical link), among other examples or combinations thereof. Wireless backhaul, midhaul, or fronthaul may be implemented via one or more IAB nodes 104, which may act as a relay using resources of an IAB donor network entity 105 (such as via a wireless link 130).

The wireless communication system 100 may include one or more of a relay 172 that may steer or reflect signals transmitted by other entities, which may support any of the described communication links. A relay 172 may include active elements or passive elements, and may be in the form of a reconfigurable intelligent surface (RIS). An RIS may include tunable reflecting antenna arrays or metasurfaces, which may be used to enhance coverage or efficiency in multipath environments.

Network entities 105 and UEs 115 each may include one or multiple antennas. Multiple antennas of such devices may be used to employ techniques such as transmit diversity, receive diversity, MIMO communication, or beamforming, and may be organized or structured as one or more antenna panels, one or more antenna groups, one or more sets of antenna elements, or one or more antenna arrays, among other examples. As used herein, the term “antenna” may refer to one or more antennas, one or more antenna panels, one or more antenna groups, one or more sets of antenna elements, or one or more antenna arrays. The term “antenna panel” may refer to a group of antennas (such as antenna elements) arranged in an array or panel, which may facilitate beamforming by manipulating parameters associated with the group of antennas. In some implementations, an antenna panel may support RF beamforming for a signal transmitted or received via an antenna port. The term “antenna module” may refer to circuitry including one or more antennas as well as one or more other components (such as filters, amplifiers, processors, beamformers) associated with integrating the antenna module into a device such as a network entity 105 or a UE 115.

Beamforming, such as directional transmission or directional reception, is a signal processing technique that may be used at a transmitting device or a receiving device (such as at a network entity 105, at a UE 115) to shape or steer a beam 175 (such as an antenna beam, a transmit beam, a receive beam) along a spatial path (such as along a direction), which may include one or more paths between a transmitting device and a receiving device. Beamforming may be achieved by combining signals communicated via multiple antenna elements of an antenna array such that signals propagating along some orientations (such as relative to the antenna array) experience constructive interference while others may experience destructive interference. Adjustments of signals communicated via the antenna elements may include a transmitting device or a receiving device applying phase offsets, amplitude offsets, or other adjustments to signals carried via (such as transmitted by, received by) antenna elements of the device, which may be defined by a beamforming weight set associated with a particular orientation (such as relative to the antenna array of the device).

Communication resources of the wireless communication system 100 (such as of a RAN 120) may refer to a resource in the frequency domain (such as a frequency resource, an RF resource), a resource in the time domain (such as a time resource), a resource in the spatial domain (such as a spatial resource, a spatial layer), or a combination thereof. The wireless communication system 100 may leverage orthogonality of such resources to convey different communications to or from different devices (such as for a communication link 125, for a communication link 135, for unicast communication, for multicast communication, for broadcast communication).

A frequency resource may refer to a frequency or range of frequencies (such as a bandwidth, a frequency channel) of a frequency band implemented for wireless communication. For example, a frequency resource may refer to a resource of a lower frequency band (such as Frequency Range 1 (FR1), between 425 MHz and 7.125 GHz), a mid-band (such as Frequency Range 3 (FR3), between 7.125 GHz and 24.25 GHz), or an upper frequency band (such as Frequency Range 2 (FR2), between 24.25 GHz and 71 GHz). Communication in the upper frequency band may be referred to as millimeter wave (mmW) communication, and communication above an upper frequency band (such as between mmW and THz frequencies, between 100 GHz and 1 THz) may be referred to as sub-Terahertz (sub-THz) communication.

A frequency resource may refer to a “carrier” (such as a frequency channel), or portion thereof, and a carrier bandwidth may be referred to as a “system bandwidth.” A carrier may be subdivided in the frequency domain, including into subcarriers, bandwidth parts (BWPs), or both. For example, a resource block (RB), such as a physical resource block (PRB), may be defined in accordance with a set of subcarriers (such as twelve consecutive subcarriers in the frequency domain), and a BWP may be configured in accordance with a set of RBs (such as a set of contiguous RBs).

A frequency resource may be configured to carry either downlink communication or uplink communication (such as in a frequency division duplexing (FDD) configuration), or may be configured to carry both downlink and uplink communication (such as in a time division duplexing (TDD) configuration, in a sub-band full duplex (SBFD) configuration). One or more numerologies for a carrier may be supported, each associated with a subcarrier spacing (SCS) and a cyclic prefix (CP). Supported numerologies may vary by frequency range (such as FR1, FR2, FR3), and a carrier may be divided into portions (such as BWPs) having the same or different numerologies. BWPs may be configured as uplink BWPs or downlink BWPs (such as by a network entity 105), including in response to network conditions (such as to allocate uplink and downlink BWPs in response to traffic conditions), device capability (such as allocating BWPs with a greater quantity of RBs to UEs 115 with relatively higher capabilities), or both. A UE 115 may be configured with a set of multiple BWPs (such as a set of uplink BWPs, a set of downlink BWPs, or both), and a single BWP of a set (such as an active UL BWP, an active DL BWP, or both) may be active at a given time, such that communication of a UE 115 is supported by active BWP(s).

A time resource may refer to a duration of a frame (such as a radio frame, a frame structure), or portion thereof. For example, a frame may span a duration of 10 ms, and each frame may be identified by a system frame number (SFN). A frame may be subdivided in the time domain, including into subframes, slots, mini-slots, or a combination thereof. Slots or mini-slots may each include a respective quantity of symbols (such as symbol durations, symbol periods, OFDM symbols), which may be a function of a configured CP. A duration of a symbol is a function of the SCS or frequency band of operation.

A spatial resource may refer to an antenna, an antenna direction, an antenna port, a signal direction (such as a beamforming direction), or other resource that supports spatial orthogonality. A device (such as a network entity 105, a UE 115) may perform communications of a given frequency resource and time resource with a single spatial resource (such as communication without regard to spatial orthogonality). Additionally, or alternatively, a device may implement multiple spatial resources to support multiple signal streams using resources that are overlapping in the time and frequency domains (such as to support MIMO techniques).

Signals of the wireless communication system 100 (such as of a RAN 120) may be communicated using one or more resource elements (REs), and an RE may refer to a resource that corresponds to one subcarrier in the frequency domain and one symbol in the time domain. An RE may be used to convey a modulation symbol corresponding to one or more bits of information (such as of a physical channel, of a reference signal) in accordance with a modulation scheme. For example, a quadrature phase shift keying (QPSK) or quadrature amplitude modulation (QAM) technique may be implemented to communicate one or more bits that are distinguished in accordance with phase components, amplitude components, or both of a signal conveyed using a RE. A quantity of bits carried by an RE may depend on an order of the modulation scheme, and a relatively higher order may correspond to a relatively higher rate of communication. A device may support communication of REs using multiple subcarriers concurrently by implementing multi-carrier modulation (MCM) techniques such as orthogonal frequency division multiplexing (OFDM) or discrete Fourier transform spread OFDM (DFT-S-OFDM), among others.

Physical channels may carry information using modulation symbols conveyed by corresponding REs. Physical shared channels (such as for communicating user data) may include a physical downlink shared channel (PDSCH) for communicating user data in a downlink direction and a physical uplink shared channel (PUSCH) for communicating user data in an uplink direction. Physical control channels (such as for managing communication via physical channels) may include a physical downlink control channel (PDCCH) for communicating downlink control information (DCI) and a physical uplink control channel (PUCCH) for communicating uplink control information (UCI). A network entity 105 may indicate (such as schedule, allocate) communication resources for a UE 115 using DCI, including indicating downlink resources of a PDSCH (such as in accordance with a downlink grant), uplink resources of a PUSCH (such as in accordance with an uplink grant), or a combination thereof. A control region (such as a control resource set (CORESET)) for a physical control channel may be configured in accordance with a pattern of REs in the time and frequency domains, and one or more control regions may be configured for a set of UEs. A UE 115 may monitor control regions for control information according to one or more search space sets, which may include a common search space set (such as for sending control information to one or more UEs 115), UE-specific search space sets (such as for sending control information to a UE 115), or a combination thereof. A physical broadcast channel (PBCH) may be used to broadcast parameters to UEs 115 to synchronize with a network entity 105 and establish communications (such as to establish a communication link 125).

Reference signals may be communicated to establish reference characteristics (such as a frequency reference, a temporal reference, a spatial reference, a signal quality reference) between devices of a RAN 120, which may support communication using physical channels. Reference signals communicated between network entities 105 and UEs 115 may include synchronization signals (such as a primary synchronization signal (PSS), a secondary synchronization signal (SSS)) that support temporal synchronization, channel state information-reference signals (CSI-RSs) that support evaluating downlink channel characteristics, sounding reference signals (SRSs) that support evaluating uplink channel characteristics, demodulation reference signals (DMRSs) that support demodulation, or phase tracking reference signals (PTRSs) for evaluating oscillator characteristics, among others. Network entities 105 and UEs 115 may receive and measure transmitted reference signals to support one or more of these and other functions.

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., the communication link(s) 125, a D2D communication link 135). HARQ may include a combination of error detection (e.g., using a cyclic redundancy check (CRC)), forward error correction (FEC), and retransmission (e.g., automatic repeat request (ARQ)). HARQ may improve throughput at the MAC layer in relatively poor radio conditions (e.g., low signal-to-noise conditions). In some examples, a device may support same-slot HARQ feedback, where the device may provide HARQ feedback in a specific slot for data received via a previous symbol of the slot. In some other examples, the device may provide HARQ feedback via a subsequent slot or according to some other time interval.

Devices of the wireless communication system 100 (e.g., wireless devices) may be configured to support one or more aspects of the described techniques for communicating HARQ feedback using pruned Huffman coding. For example, a UE 115 may include a processing system 140, and a network entity 105 may include a processing system 145, each of which may be configured to cause the respective device to perform (such as being configured as means for performing) one or more of the described operations. By configuring a processing system 140, a processing system 145, or a combination thereof in accordance with the described techniques, the communication system 100 (such as the RAN 120) may enable wireless devices (e.g., UE 115, network entity 105) to implement pruned compression coding configurations (e.g., pruned Huffman coding configurations), which may replace low-probability, lengthy “nodes” in a binary coding tree (e.g., Huffman tree) with set quantities of equally probable (e.g., equiprobable) bits.

For example, wireless devices may communicate one or more conditions or rules associated with a pruned binary coding configuration (e.g., pruned Huffman coding configuration) for pruning a Huffman tree, such as conditions which limit a Huffman tree depth, a threshold quantity of bits for a codeword, a threshold quantity of codeword length groups, a threshold quantity of steps for channel encoding or decoding, or any combination thereof. After determining some feedback bits, a wireless device may generate a Huffman tree and prune the Huffman tree according to the one or more conditions of the pruned binary coding configuration. By replacing one or more nodes of the Huffman tree with equiprobable bits, the codeword lengths may be reduced and the quantity of codeword length groups may be less variable. This may aid in channel encoding and decoding due to the lower codeword length variability. In some cases, this may result in less compression than using a full Huffman code (e.g., more bits, higher entropy), but may still be advantageous compared to other coding implementations, such as linear coding or two-part HARQ-ACK coding. For example, by implementing a pruned Huffman coding, the described techniques can be used to reduce processing and latency associated with channel encoding and decoding for variable codewords.

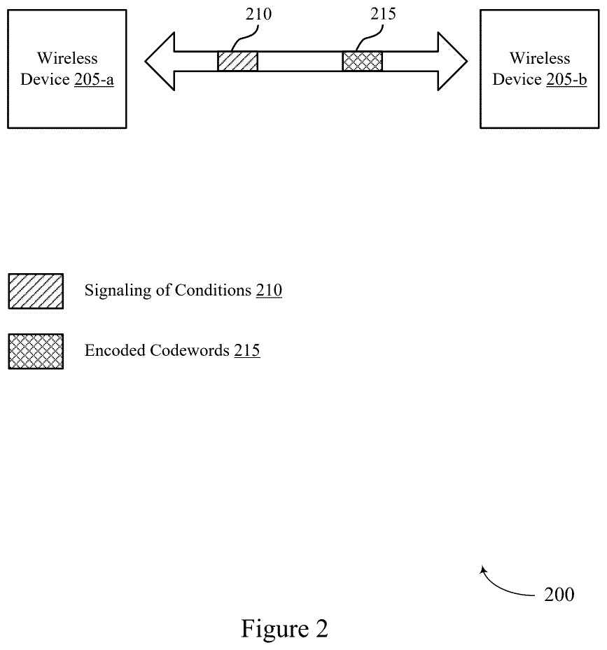

FIG. 2 shows an example of a signaling configuration 200 that supports techniques for communicating HARQ feedback using pruned Huffman coding. The signaling configuration 200 may implement or be implemented to realize aspects of the wireless communications system 100. For example, the signaling configuration 200 may illustrate communication between a wireless devices 205-a and a wireless device 205-b, which may be examples of corresponding signaling described herein, including with reference to FIG. 1. Signaling configuration 200 may support signaling of conditions 210 for generating pruned binary coding trees (e.g., pruned Huffman coding trees), as well as communication of encoded codewords 215, between wireless devices 205, where the encoded codewords 215 may be encoded and decoded using the pruned binary coding trees.

In some wireless communications systems, wireless devices 205 may communicate with one another, and may exchange feedback signaling (e.g., HARQ feedback) to indicate successful (or unsuccessful) reception of one or more messages, or message retransmissions, from the other wireless device 205. For example, wireless device 205-a may transmit HARQ feedback to wireless device 205-b after receiving, or failing to receive, one or more messages from wireless device 205-b.

In some implementations, HARQ feedback may contain multiple bits, where each bit may indicate successful reception of a message (e.g., an ACK bit) or, alternatively, unsuccessful reception of a message (e.g., a NACK bit). That is, a HARQ feedback message may contain multiple ACK/NACK bits to indicate successful (or unsuccessful) reception of multiple messages. In some cases, the probability of a bit of the HARQ feedback being an ACK bit may be higher than a probability of a bit being a NACK bit. In some examples, the ACK/NACK bits may also be correlated, such that the probability associated with each bit of the HARQ feedback may be linked or related.

In some wireless communications systems (e.g., NR), a wireless device 205 transmitting HARQ feedback may not implement any source coding or compression. For example, the ACK/NACK bits may be directly mapped to ‘0’ and ‘1’, and encoded with a linear code. In some examples, a Reed-Muller code may be used for control blocks including a small quantity of ACK/NACK bits (e.g., between 3 and 11 ACK/NACK bits). In other examples, a polar code may be used for larger quantities of ACK/NACK bits (e.g., 12 or more ACK/NACK bits). However, linear encoding without any source coding or compression may result in high overhead for transmitting HARQ messages (e.g., a high entropy).

In some implementations, a wireless device 205 transmitting a HARQ message may encode and compress the HARQ message (e.g., reduce the quantity of bits of an ACK/NACK sequence) and may transmit encoded codewords 215. In some cases, the wireless device 205 may implement a multi-part HARQ compression scheme, such as a two-part HARQ compression scheme. A multi-part HARQ compression scheme may be implemented to reduce an average payload size, while limiting a variability of a source codeword, which may reduce channel encoding complexity. However, a multi-part HARQ compression scheme may result in a partitioning problem. That is, it may not be clear how to divide or partition the different bits of the HARQ feedback based on different constraints. Implementing the multi-part HARQ compression scheme may be based on brute force enumeration of the partitions, which may be inefficient.

In some implementations, lossless and high compression (e.g., optimal) source coding may be obtainable for messages, including HARQ feedback, such as by using Huffman coding. Huffman coding may be a lossless (e.g., optimal, minimal bits, high compression) source coding that may use series of bits, or codewords (e.g., Huffman codewords), to represent possible bit sequences (e.g., ACK/NACK sequences) for a message (e.g., HARQ feedback). The Huffman codewords may be assigned or mapped to the possible bit sequences based on probability, such that fewer bits are used to encode more probable codewords. In other words, Huffman coding (e.g., Huffman tree source coding) may be a recursive algorithm to obtain a minimum expected source codeword length.

For example, a source vector x (e.g., a HARQ message) may have M different symbols, x₁, . . . , x_{M}, (e.g., ACK/NACK bits) where each symbol may be associated with a known probability, pₘ, where m=1, . . . , M and p₁≥p₂≥ . . . ≥p_{M}. If M=3, then the source codeword may be compressed into codewords, CW, such that CW₁=‘0’ (associated with x₁), CW₂=‘10’ (associated with x₂), and CW₃=‘11’ (associated with x₃). The codewords may be prefix-free. For M>3, the two least probable symbols (e.g., x_{M-1} and x_{M}) may be merged into an internal tree node within a Huffman tree, and distinguished on the Huffman tree by a single bit. By merging the two least probable bits, the internal tree node may be represented as a virtual symbol x′_{M-1}. The internal tree node x′_{M-1} may be associated with a probability p′_{M-1}=p_{M-1}+p_{M}. Then, the reduced set of M−1 symbols may be encoded where, if M−1=3, the source may be compressed into the codewords CW₁=‘0’ (associated with x₁), CW₂=‘10’ (associated with x₂), and CW₃=‘11’ (associated with x′_{M-1}). Otherwise, the two least probable symbols of the reduced set of M−1 symbols (x₁, x₂, . . . , x_{M-2}, x″_{M-2}) may be merged, as described with reference to x_{M-1} and x_{M}, and a new virtual symbol, x′_{M-2}, may be generated. These steps may be repeated until all possible source codewords are encoded, resulting in a Huffman tree where the least probable symbol combinations for the source codeword are deeper in the Huffman tree, or have longer compressed codewords. In other words, this Huffman coding may result in more probable bit sequences being associated with shorter codewords, and less probable bit sequences being associated with longer codewords. As such, Huffman coding may result in a high variability of resulting codeword lengths, which may increase channel coding complexity (e.g., may be cumbersome to implement for channel encoding and decoding).

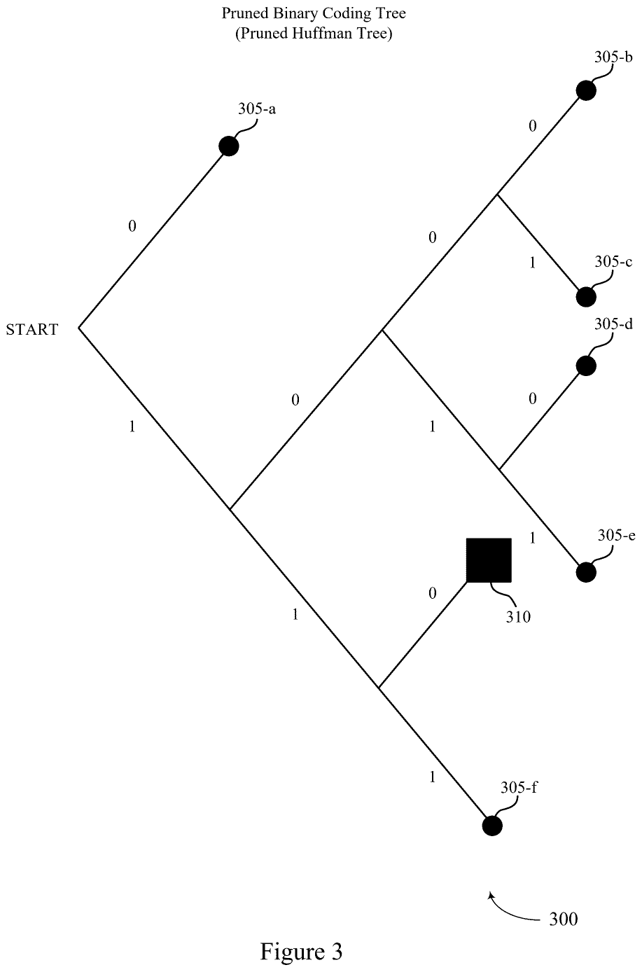

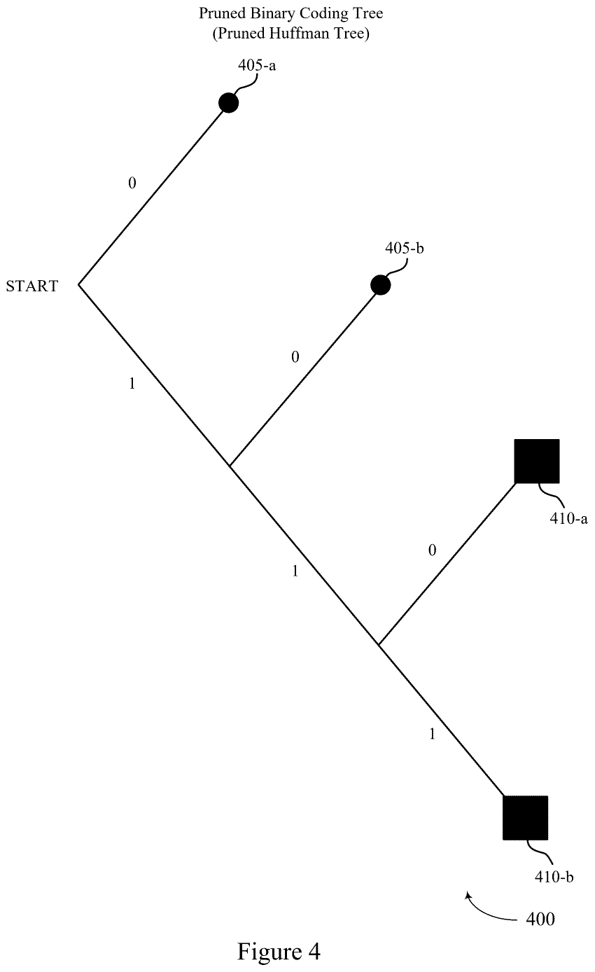

In some cases, compression coding configurations, such as Huffman coding configurations, may be pruned and used as a source encoder. That is, a full Huffman tree (e.g., optimal Huffman code) may be pruned to reduce a codeword length variability, or based on other factors, while still maintaining the highest compression for the most probable source codewords. For example, nodes of the Huffman tree that may be relatively long (e.g., less probable) may be replaced with equiprobable bits, as described further with reference to FIGS. 3 and 4. As it is used herein, the term “equiprobable bits” may be used to refer to a set of multiple bits (e.g., two or more) that may form a corresponding set of codewords of equal lengths and thus may represent equally-probable codewords in a full binary coding tree. In the pruned binary coding tree, the codewords corresponding to the equiprobable bits may have variable probabilities of being communicated by a wireless device, but may all be represented with codewords of equal lengths based on the set of equiprobable bits. That is, a set of equiprobable bits generates a set of codewords of equal lengths within a pruned binary coding tree, replacing codewords of varying lengths. As such, a first codeword corresponding to (e.g., represented by) a first equiprobable bit may have the same probability of being communicated by a wireless device as a second codeword corresponding to (e.g., represented by) a second equiprobable bit. By pruning the Huffman tree, the most prominent (e.g., most probable) source codewords may be maintained, while the variability of the source codeword length may be limited. This may facilitate less complex channel coding (e.g., separate source-channel coding (SSCC)). There may be no need to solve a complex multi-part (e.g., two part) partitioning problem, as associated with a multi-part HARQ-ACK compression scheme. In some examples, by pruning the Huffman binary code tree, there may be an increased average source codeword length, but a reduced maximal source codeword length and a reduced quantity of source codeword length groups, as compared to the full Huffman coding (e.g., optimal Huffman code).

In some examples, pruning (e.g., sensible pruning) for a binary coding tree (e.g., Huffman tree) may be apparent or intuitive from the full binary tree (e.g., full Huffman tree) structure. For example, one node may extend significantly longer than other nodes, and thus may be a good place to implement pruning. In some examples, pruning the binary coding tree (e.g., the Huffman tree) may allow for reassignment of source codewords to newly vacant branches after the pruning. This may further reduce an average codeword length, and improve a block error rate (BLER) performance of the SSCC scheme. In some cases, to prune a Huffman tree, l may be a quantity of “leaves” under an internal node in the Huffman tree, where the leaves may be the end of a branch of the Huffman tree. To prune the Huffman tree, the internal node and all descending branches may be replaced with a fully-populated tree with 2^{log}^{₂}^{l} leaves.

In some cases, the Huffman pruning may be implemented in accordance with one or more rules, conditions, or restrictions, such as limiting the maximum quantity of possible source codeword lengths, the quantity of different codeword length groups, a pruned tree depth, a quantity of separate coding steps, a quantity of separate decoding steps, or any combination thereof. For example, a wireless device 205, such as the wireless device 205-a or the wireless device 205-b, may receive or transmit some signaling of conditions 210, which may indicate the one or more rules, conditions, or restrictions for a pruned compression coding configuration (e.g., pruned Huffman coding configuration). That is, signaling of conditions 210 may indicate rules, conditions, or restrictions for “pruning” a full binary coding tree (e.g., full Huffman coding tree) to generate a “pruned” binary coding tree (e.g., pruned Huffman tree).

Continuing with the same example, the wireless device 205-a, may identify a set of HARQ feedback bits to be transmitted to the wireless device 205-b. In such cases, the wireless device 205-a may generate a full binary coding tree (e.g., full Huffman coding tree) based on the HARQ feedback bits, and may subsequently “prune” the full binary coding tree to generate the pruned binary coding tree (e.g., pruned Huffman tree) based on the signaling of conditions 210. The wireless device 205-a may encode a HARQ feedback message, or some other codeword, to generate encoded codewords 215 in accordance with the pruned binary coding tree (e.g., pruned Huffman tree). The wireless device may transmit the encoded codewords 215 to the wireless device 205-b. The wireless device 205-b may use the signaling of conditions 210 and the encoded codewords 215 in order to decode the encoded codewords 215 in accordance with the pruned Huffman tree.

Although the pruned compression coding configurations (e.g., pruned Huffman coding configurations) described herein are primarily described with reference to feedback messages, and ACK/NACK bits, the pruned compression coding configurations described herein may be applied for any compressed codeword where compression coding may be implemented. In particular, any message that may benefit from less codeword length variability may implement a pruned Huffman code.

FIG. 3 shows an example of a binary coding tree diagram 300 (e.g., Huffman tree diagram) that supports techniques for communicating HARQ feedback using pruned compression coding configurations (e.g., pruned Huffman coding configurations). The binary coding tree diagram 300 may implement or be implemented to realize aspects of the wireless communications system 100 or the signaling configuration 200. For example, the binary coding tree diagram 300 illustrates a pruned binary coding tree (e.g., pruned Huffman tree) for independent and identically distributed (IID) bits, which may be an example of pruned Huffman coding corresponding to signaling described herein, including with reference to FIGS. 1 and 2.

In some wireless communications systems, pruned binary coding configurations (e.g., pruned Huffman coding configurations) may be implemented for source coding and compressing for messages, such as HARQ feedback, between wireless devices. That is, an internal node (e.g., node 310) of a binary coding tree may be “pruned” and, in some cases, may be replaced with equiprobable bits, rather than variable length branches, which may reduce a codeword length variability for the encoded messages. In particular, the node 310 may be pruned and replaced with equiprobable bits in accordance with the predetermined and/or pre-signaled conditions for the pruned compression coding configuration (e.g., conditions indicated via the signaling of conditions 210 in FIG. 2).

For example, the node 310 may be pruned to achieve a pruned binary coding tree depth, a maximum codeword length (e.g., to reduce the maximum codeword length), to reduce the quantity of codeword length groups, etc. Stated differently, multiple “branches” of the binary coding tree extending from the node 310 may be replaced and represented by equiprobable bits, such that all the codewords associated with the “branches” extending from the node 310 may be associated with an equal probability of being used.

In some implementations, the HARQ feedback may include IID bits. IID bits may each be independently associated with a probability and may not be correlated (e.g., value of one bit may not affect the value of another bit). For example, a HARQ feedback message may include 5 IID ACK/NACK bits. The binary coding tree diagram 300 may be an example of a pruned binary coding tree (e.g., pruned Huffman tree) for 5 IID ACK/NACK bits. For example, the binary coding tree diagram 300 may include leaves 305, which may have been included in a full Huffman tree associated with 5 IID bits. Each of the leaves 305 may indicate or otherwise represent a codeword (e.g., Huffman codeword) of the binary coding tree. For example, the leaf 305-a may be represented by codeword ‘0,’ where the leaf 305-b may be represented by the codeword ‘1000.’

However, at node 310, a branch of the Huffman tree may be pruned in accordance with the conditions for the pruned compression coding configuration. The pruned branch may have included 26 leaves 305, or 26 possible codewords (e.g., codewords 7-32), with a maximum codeword length of 13 bits and 9 different length groups. For the purposes of the present disclosure, the term “codeword length group” or “length group” may be used to refer to the quantity or number of bits used to indicate a codeword (e.g., the “length” of the codeword). For example, the leaf 305-a may exhibit a codeword length of one (e.g., one bit, ‘0’), whereas the leaf 305-f may exhibit a codeword length of three (e.g., three bits ‘111’).

To generate a pruned Huffman tree, the node 310 may be replaced with 5 equiprobable bits. Each of the 26 leaves 305 (e.g., codewords) that may have originally been included within the Huffman tree after node 310 may be represented by 8 bits (e.g., ‘110’ and a permutation of the 5 equiprobable bits). Although the node 310 may be able to represent 32 codewords, which may be less compressed than the full Huffman tree, the pruned Huffman tree may have a maximal codeword length of 8 bits and may have four different codeword length groups (e.g., 1 bit, 3 bits, 4 bits, 8 bits). Based on the pruning, codewords for the binary coding tree diagram 300 may be less complex to code during channel coding.

In some cases, an entropy of a coding and compression scheme may be used to evaluate the effectiveness of the coding and compression scheme, as compared to a source entropy (e.g., a lower bound of compression efficiency). For IID bits, the entropy of a compression scheme may be determined based on some probabilities associated with possible codewords for a message, and on some frequencies of the different codewords. For example, the probability of a bit being an ACK may be represented by P_{ACK}. For example, P_{ACK}=P(1)=0.9, or the probability of an ACK/NACK bit being an ACK may be 90%. The quantity of uncompressed ACK/NACK bits, k, may be 5. Each codeword may be associated with a probability for a codeword to contain a particular arrangement of bits. Because the bits may be IID bits, a probability may be associated with all possible permutations of a codeword. For example, ‘11011’ may be associated with the same probability as a codeword ‘01111’. The probabilities, based on a quantity of ACK bits, may be determined by P=P₁*P₂*P₃*P₄*P₅ for each possible codeword, where P_{Z} may be the probability associated with a Z bit. For 5 IID bits, the probabilities may be
P_{ALL-ACK}=P_{#5}=0.59049, P_{#4}=0.06561, P#3=0.00729, P_{#2}=0.00081, P_{#1}=9·1e⁻⁵, P_{ALL-NACK}=P_{#0}=1e⁻⁵, where P_{#Y} may be the probability of a codeword with Y quantity of ACK bits.

In this regard, the probability of each codeword may be associated with a supported frequency. The supported frequencies may identify the quantity of possible permutations associated with each probability. For example, there may only be one codeword that includes all ACK bits, but there may be five possible codewords with one NACK bit, and five possible codewords with one ACK bit. There may be ten possible codewords with two NACK bits, and ten possible codewords with two ACK bits. Thus, the supported frequencies for 5 IID bits may be [1 5 10 10 5 1], which indicates the number of possible permutations associated with each probability (e.g., 1 codeword that includes all ACK bits, 5 codewords that include 4 ACK bits, 10 codewords that include 3 ACK bits, 10 codewords that include 2 ACK bits, 5 codewords that include 1 ACK bit, and 1 codeword that includes 0 ACK bits).

In some examples, a source entropy associated with 5 IID bits may be 2.345 bits. A two-part HARQ-ACK compression may result in an entropy of 2.91 bits (e.g., N₁=2, where N₁ may be the quantity of compression steps, parts, or segments, such that N₁=2 may indicate a two-part HARQ-ACK compression). A full Huffman tree (e.g., full Huffman coding) may have an entropy of 2.4 bits. To calculate an entropy for the pruned Huffman tree, the length of the possible codewords and the associated probabilities may be combined, as in Equation 1:

E[l]=1 bit*0.59049+3 bit*0.06561+4 bit*(4*0.06561)+(3+5 (1)

where P_{c} may be an aggregate probability of the 5 equiprobable bits of the node 310 for the pruned tree, calculated by summing P_{#Y}*f for the codewords (e.g., leaves) pruned at the node 310, where f may be the quantity of codewords associated with P_{#Y} for the codewords pruned at the node 310. Thus, the entropy of the pruned Huffman tree may be 2.49 bits, which may be greater than the full Huffman tree, but less than the two-part compression scheme, and may be associated with reduced codeword length and length groups (e.g., a reduced codeword length variability).

To channel encode (e.g., SSCC) the codewords generated using the pruned binary coding tree (e.g., pruned Huffman tree), such as the binary coding tree diagram 300, an encoding wireless device may follow a series of steps. For example, the encoding wireless device may identify the HARQ bits to be sent, and may generate pruned Huffman codewords based on a pruned Huffman tree, where the pruned Huffman tree is generated in accordance with a set of predetermined or negotiated conditions (e.g., conditions indicated via the signaling of conditions 210 in FIG. 2). Then, the encoding wireless device may encode each set of bits of the Huffman codewords based on possible codeword lengths (e.g., the different length groups).

For example, for k=5 uncompressed, IID source bits, the pruned Huffman codewords corresponding to the binary coding tree diagram 300 may be of length 1 bit, 3 bits, 4 bits, or 8 bits. The encoding wireless device may encode the first bit of the codeword into n₁ coded bits, where n₁ may be based on the coding scheme. If there are no further bits to encode, the encoding wireless device may stop. If there are further bits to encode, the encoding wireless device may encode the next two bits of the generated codeword into n₂ coded bits. If there are no further bits to encode (e.g., for a three bit codeword), the encoding wireless device may stop. If there are further bits to encode, the encoding wireless device may encode the next bit of the generated codeword into n₃₁ coded bits (e.g., for a four bit codeword). If there are five bits left in the codeword, the encoding wireless device may encode the next 5 bits into n₃₂ coded bits (e.g., for an eight bit codeword).

To channel decode (e.g., SSCC) the codewords generated using the pruned binary coding tree (e.g., pruned Huffman tree), such as the binary coding tree diagram 300, a decoding wireless device may follow a series of steps. The decoding wireless device may first decode sets of bits based on the channel encoding scheme and the possible codeword lengths. Then, the decoding wireless device may decompress (e.g., source-decode) the decoded pruned Huffman codeword and recover the uncompressed k bits. For example, for 5 uncompressed, IID source bits, the decoding wireless device may receive an encoded codeword and may decode a first n₁ bits of the encoded codeword. If the decoded bit is ‘0’, the decoding wireless device may stop channel decoding and move to decompression. For instance, referring to FIG. 3, if the first decoded bit is ‘0,’ the decoding device may identify the codeword represented by the leaf 305-a, and may decompress the codeword to retrieve/decode the original HARQ bit sequence represented by the codeword/leaf 305-a.

Otherwise, if the first decoded bit is ‘1,” the decoding wireless device may channel-decode the next n₂ bits. If the decoded bits are ‘11’ (resulting in ‘111’ with the first decoded bit), the decoding wireless device may stop channel decoding and move to decompression. For instance, referring to FIG. 3, if the first three bits are ‘111,’ the decoding device may identify the codeword represented by the leaf 305-f, and may decompress the codeword to retrieve/decode the original HARQ bit sequence represented by the codeword/leaf 305-f.

Conversely, if the second two decoded bits are ‘10’ (resulting in ‘110’ with the first decoded bit), the decoding wireless device may decode the next n₃₂ bits and then stop channel decoding and move to decompression. For instance, referring to FIG. 3, if the first three bits are ‘110,’ the decoding device may identify the pruned node 310, and may have to decode the next n₃₂ bits which were pruned from the node 310 in order to identify and decompress the received codeword.

Comparatively, if the second two decoded bits are ‘00’ or ‘01’ (resulting in ‘100’ or ‘101’ with the first decoded bit), the decoding wireless device may decode the next n₃₁ bits and then stop channel decoding and move to decompression. For instance, referring to FIG. 3, if the first three bits are ‘100’ or ‘101,’ the decoding device may have to continue decoding additional bits in order to identify and decompress the received codeword (e.g., codeword represented by one of the leaves 305-b, 305-c, 305-d, and 305-e).

To decompress the channel decoded codewords (e.g., decoded pruned Huffman codeword), which may be of some known length (e.g., 1, 3, 4, 8 bits for 5 IID bits), the decoding wireless device may generate the pruned Huffman tree and decompress the Huffman codeword back into uncompressed source bits (e.g., 5 uncompressed source bits). In some cases, the decoding wireless device may generate the pruned Huffman tree prior to channel decoding and may use the pruned Huffman tree to determine the series of steps for channel decoding (e.g., the grouping of sets of bits for decoding).

In some cases, implementing a pruned binary coding configuration (e.g., pruned Huffman coding configuration) may have a notable effect in reducing BLER and a signal-to-noise ratio (SNR) for encoded codewords, as compared to linear coding without compression and a multi-part HARQ compression scheme. For example, for k=5 ACK/NACK bits (e.g., IID bits), and using n=32 coded bits, an additive white Gaussian noise (AWGN) model may predict the pruned Huffman HARQ-ACK compression scheme, using a same average resource and a fixed power per resource, to have a 1 dB gain of SNR at 0.1 BLER, as compared to a two-part HARQ-ACK compression scheme using a same average resource and a fixed power per resource. The same pruned Huffman HARQ-ACK compression scheme may have a 0.3 dB gain of SNR at 0.01 BLER, as compared to the two-part HARQ-ACK compression scheme.

In some cases, codewords associated with a pruned Huffman tree node, such as node 310, may be reassigned. In some examples, a node may be pruned and may not be replaced, or may have excess bits (e.g., at node 310, 26 codewords may be replaced by 5 equiprobable bits, which may be able to support 32 codewords, introducing 6 extra possible codewords that could be reassigned). If a node is empty or has vacant space, some codewords of a large, pruned node may be reassigned to the empty node to further reduce the codeword length and codeword length variability. In some aspects, the rules, conditions, or restrictions regarding how nodes 310 and/or leaves 305 are to be reassigned may be defined or otherwise determined based on the signaling of conditions 210 in FIG. 2.

For example, for a HARQ message including 11 IID bits when uncompressed (e.g., k=11), with an associated P_{ACK}=P(1)=0.9, a corresponding Huffman tree may include a leaf 305, of a support probability of 0.3138, for a codeword of all ACK bits (e.g., compressed codeword ‘00’). The Huffman tree may include 8 original Huffman codewords (e.g., leaves 305) of length 8 bits, and three original Huffman codewords of length 4 bits. In some cases, the Huffman tree may be pruned to replace all Huffman codewords off a branch ‘10’ (e.g., at a first node), which may be (2¹¹−12) codewords, with 11 equiprobable bits. The Huffman tree may also be pruned, without replacement, for any Huffman codeword off a branch ‘1100’. For example, one node may be left empty or vacant. Based on the empty node, some quantity of codewords (e.g., leaves) may be reassigned from the first node to the empty node. For example, 55 codewords of the (2¹¹−12) codewords at the first node may be moved to the empty or vacant node. The first node may thus include (2¹¹−12−55) codewords, represented by 11 equiprobable bits, while the empty node may represent 55 codewords, represented by 6 trailing bits (e.g., 10 total bits for a codeword). In some examples, reassignment of codewords may move more probable codewords to branches that may include fewer bits, which may lower an entropy, reduce the average codeword length, or both. In some examples, a source entropy for 11 uncompressed, IID bits may be 5.159 bits. The entropy of the full Huffman tree may be 5.2061 bits, and the entropy of the two-part HARQ-ACK compression scheme (e.g., N₁=2) may be 5.7155 bits. The entropy of the pruned Huffman tree may be 5.7288 bits, but the pruned Huffman tree after reassignment may include a reduced average codeword length.

In some examples, implementing a pruned binary coding tree (e.g., pruned Huffman tree) with reassignment may have a notable effect in reducing BLER and SNR for encoded codewords, as compared to linear coding without compression and a multi-part HARQ compression scheme. For example, for k=11 ACK/NACK bits, and using n=32 coded bits, an AWGN model may predict the pruned Huffman HARQ-ACK compression scheme, using a same average resource and a fixed power per resource, to have a 0.2 dB gain of SNR at 0.1 BLER, as compared to a two-part HARQ-ACK compression scheme, using a same average resource and a fixed power per resource. The same pruned Huffman HARQ-ACK compression scheme may have a 0.1 dB gain of SNR at 0.01 BLER, as compared to the two-part HARQ-ACK compression scheme.

FIG. 4 shows an example of a binary coding tree diagram 400 (e.g., Huffman tree diagram) that supports techniques for communicating HARQ feedback using pruned compression coding configurations (e.g., pruned Huffman coding configurations). The binary coding tree diagram 400 may implement or be implemented to realize aspects of the wireless communications system 100 or the signaling configuration 200. For example, the binary coding tree diagram 400 illustrates a pruned Huffman tree for correlated bits, which may be an example of pruned Huffman coding corresponding to signaling described herein, including with reference to FIGS. 1 and 2.

In some wireless communications systems, pruned binary coding configurations (e.g., pruned Huffman coding configurations) may be implemented for source coding and compressing for messages, such as HARQ feedback, between wireless devices. That is, an internal node of a binary coding tree (e.g., node 410-a, node 410-b) may be “pruned” and, in some cases, may be replaced with equiprobable bits, rather than variable length branches, which may reduce a codeword length variability for the encoded messages. As described previously herein, nodes of a full binary coding tree (e.g., full Huffman tree) may be pruned in accordance with conditions of a pruned binary coding configuration.

In some implementations, the HARQ feedback may include correlated bits (e.g., the value of a bit may be associated with or related to the value of another bit). Correlated bits may each be associated with each other according to some correlation factor, ρ. For example, for correlated ACK/NACK bits, which may be ‘0’ or ‘1,’ the correlation factor may be used to determine how correlated the bits may be. In some examples, a bit of ‘0’ may be correlated with another ‘0’ bit according to pρ+(1−p), where p may be the probability associated with the ‘1’ bit. A bit of ‘1’ may be correlated with another ‘1’ bit according to p+(1−p)ρ. A bit of ‘0’ may be correlated with a ‘1’ bit according to p(1−ρ), while a bit of ‘1’ may be correlated with a bit of ‘0’ according to (1−p)(1−ρ). That is, the correlated bits may be correlated or otherwise associated with one another according to the probability and correlation factor such that there is some relation between the bits in the feedback message, which may make some combinations of bits more likely or more probable.

For example, a HARQ feedback message may include 5 correlated ACK/NACK bits. The binary coding tree diagram 400 may be an example of a pruned Huffman tree for 5 correlated ACK/NACK bits. For example, the binary coding tree diagram 400 may include leaves 405, which may have been included in a full Huffman tree associated with 5 correlated bits. However, at nodes 410-a and 410-b, branches of the Huffman tree may be pruned (e.g., in accordance with conditions for a pruned binary coding configuration, such as a pruned Huffman coding configuration). At node 410-a, a branch of the Huffman tree may be pruned, and 26 codewords (e.g., branches) may be replaced with 5 equiprobable bits. At node 410-b, four codewords (e.g., branches) may be replaced with 2 equiprobable bits (e.g., tight pruning). At node 410-b, replacing the four codewords with 2 bits may help regulate the quantity of length groups, and may not introduce excess bits. The full Huffman tree, prior to pruning may have included a maximal source codeword length of 17 bits and 11 different length groups. After the pruning, as in the binary coding tree diagram 400, the pruned Huffman tree may have a maximal codeword length of 8 bits and 4 different codeword length groups (e.g., 1 bit, 2 bits, 5 bits, 8 bits). Based on the pruning, codewords for the binary coding tree diagram 300 may be less complex to code during channel coding.

In some cases, an entropy of a coding and compression scheme may be used to evaluate the effectiveness of the coding and compression scheme, as compared to a source entropy (e.g., a lower bound of compression efficiency). The entropy of a compression scheme for correlated bits may be determined based on some probabilities associated with possible codewords for a message and on the correlation factor. For example, the probability of a bit being an ACK may be some P_{ACK}. For example, a P_{ACK}=P(1)=0.9, or the probability of an ACK/NACK bit being an ACK may be 90%. The quantity of uncompressed, correlated ACK/NACK bits, k, may be 5. The correlation factor may be ρ=0.9. Each codeword may be associated with a support probability, or a probability for a codeword to contain a particular arrangement of bits, which may be based on P_{ACK} and on ρ. The support probabilities, based on a quantity of ACK bits, may be determined by P=P₁*f(P₂,ρ)*f(P₃,ρ)*f(P₄,ρ)*f(P₅,ρ) for each possible codeword, where f(P_{Z},ρ) may be the conditional probability associated with an associated Z bit, and P_{Z} may be the probability associated with a Z bit. For example, for 5 correlated bits, the support probability that a HARQ message may be 5 ACK bits may be P=P₁*(p+(1−p)ρ)⁴=0.9*0.994=0.8645. The support probability that a HARQ message may be 5 NACK bits may be P=P₁*(pρ+(1−p))⁴=0.1*0.914=0.0686. Because correlated bits may depend on the preceding bit in a series, there may be 11 different support probabilities for 5 correlated bits. However, after pruning, the nodes 410-a and 410-b may be replaced with equiprobable bits, and the support probability may be combined, such that the probability of a codeword being contained in node 410-a may be 0.0393 and the probability of a codeword being contained at 410-b may be 0.296.

In some examples, a source entropy associated with 5 correlated bits may be 0.9344 bits. A two-part HARQ-ACK compression may result in an entropy of 1.6775 bits (e.g., N₁=1). A full Huffman coding may have an entropy of 1.364 bits. To calculate an entropy for the pruned Huffman tree, the length of the possible codewords and the associated support probabilities may be combined, as in Equation 2:

E[l]=1 bit*0.8645+2 bit*0.686+(3+2) bit*(0.0296)+(3+5)bi (2)

where P_{c} may be an aggregate probability of the 5 equiprobable bits of the node 410-a for the pruned tree. Thus, the entropy of the pruned Huffman tree may be 1.4481 bits, which may be greater than the full Huffman tree, but less than the two-part compression scheme, and may be associated with reduced codeword length and length groups, as compared to the full Huffman tree (e.g., a reduced codeword length variability).

To channel encode (e.g., SSCC) the codewords generated using the pruned Huffman tree, such as the binary coding tree diagram 300, an encoding wireless device may follow a series of steps. For example, the encoding wireless device may generate a pruned Huffman codeword based on a pruned Huffman tree. Then, the encoding wireless device may encode each set of bits of the Huffman codeword based on possible codeword lengths (e.g., the different length groups). For example, for k=5 uncompressed, correlated source bits, the pruned Huffman codeword corresponding to the binary coding tree diagram 400 may be of length 1 bit, 2 bits, 5 bits, or 8 bits. The encoding wireless device may encode the first bit of the codeword into n₁ coded bits, where n₁ may be based on the coding scheme. If there are no further bits to encode, the encoding wireless device may stop. If there are further bits to encode, the encoding wireless device may encode the next bit of the generated codeword into n₂ coded bits. If there are no further bits to encode (e.g., for a two bit codeword), the encoding wireless device may stop. If there are further bits to encode, the encoding wireless device may encode the next bit of the generated codeword into n₃ coded bits. If there are two bits left in the codeword, the encoding wireless device may encode the next two bits into n₄₁ coded bits (e.g., for a five bit codeword). If there are five bits left in the codeword, the encoding wireless device may encode the next 5 bits into n₄₂ coded bits (e.g., for an eight bit codeword).

To channel decode (e.g., SSCC) the codewords generated using the pruned Huffman tree, such as the binary coding tree diagram 400, a decoding wireless device may follow a series of steps. The decoding wireless device may first decode sets of bits based on the channel decoding scheme and the possible codeword lengths. Then, the decoding wireless device may decompress (e.g., source-decode) the decoded pruned Huffman codeword and recover the uncompressed k bits.

For example, for 5 uncompressed, correlated source bits, the decoding wireless device may decode a first n₁ bits. If the decoded bit is ‘0’, the decoding wireless device may stop channel decoding and move to decompression. For instance, referring to FIG. 4, if the first decoded bit is ‘0,’ the decoding device may identify the codeword represented by the leaf 405-a, and may decompress the codeword to retrieve/decode the original HARQ bit sequence represented by the codeword/leaf 405-a.

Otherwise, if the first decoded bit is ‘1,’ the decoding wireless device may channel-decode the next n₂ bits. If the next decoded bit is ‘0’ (resulting in ‘10’ with the first decoded bit), the decoding wireless device may stop channel decoding and move to decompression. For instance, referring to FIG. 4, if the first two bits are ‘10,’ the decoding device may identify the codeword represented by the leaf 405-b, and may decompress the codeword to retrieve/decode the original HARQ bit sequence represented by the codeword/leaf 405-b.

Conversely, if the second decoded bit is ‘1,’ the decoding wireless device may channel-decode the next n₃ bits. If the next decoded bit is ‘1’ (resulting in ‘111’), the decoding wireless device may decode the next n₄₁ bits (represented by pruned node 410-b) and then stop channel decoding and move to decompression. Otherwise, if the decoded bit is ‘0’ (resulting in ‘110’), the decoding wireless device may decode the next n₄₂ (represented by pruned node 410-a) bits and then stop channel decoding and move to decompression. To decompress the channel decoded codewords (e.g., decoded pruned Huffman codeword), which may be of some known length (e.g., 1, 2, 5, 8 bits for 5 correlated bits), the decoding wireless device may generate the pruned Huffman tree and decompress the Huffman codeword back into uncompressed source bits (e.g., 5 uncompressed source bits). In some cases, the decoding wireless device may generate the pruned Huffman tree prior to channel decoding and may use the pruned Huffman tree to determine the series of steps for channel decoding (e.g., the grouping of sets of bits).

In some cases, implementing a pruned Huffman code may have a notable effect in reducing BLER and SNR for encoded codewords, as compared to linear coding without compression and a multi-part HARQ compression scheme, for correlated source bits. For example, for k=5 ACK/NACK bits that are correlated according to ρ=0.9, and using n=32 coded bits, an AWGN model may predict the pruned Huffman HARQ-ACK compression scheme, using a same average resource and a fixed power per resource, to have a 1.4 dB gain of SNR at 0.01 BLER, as compared to a two-part HARQ-ACK compression scheme, using a same average resource and a fixed power per resource.

In some implementations, as described with respect to FIG. 3, one or more codewords associated with a node, such as a node in the binary coding tree diagram 400, may be reassigned to empty, pruned nodes or nodes with excess space. This may further reduce an average codeword length, among other advantages.

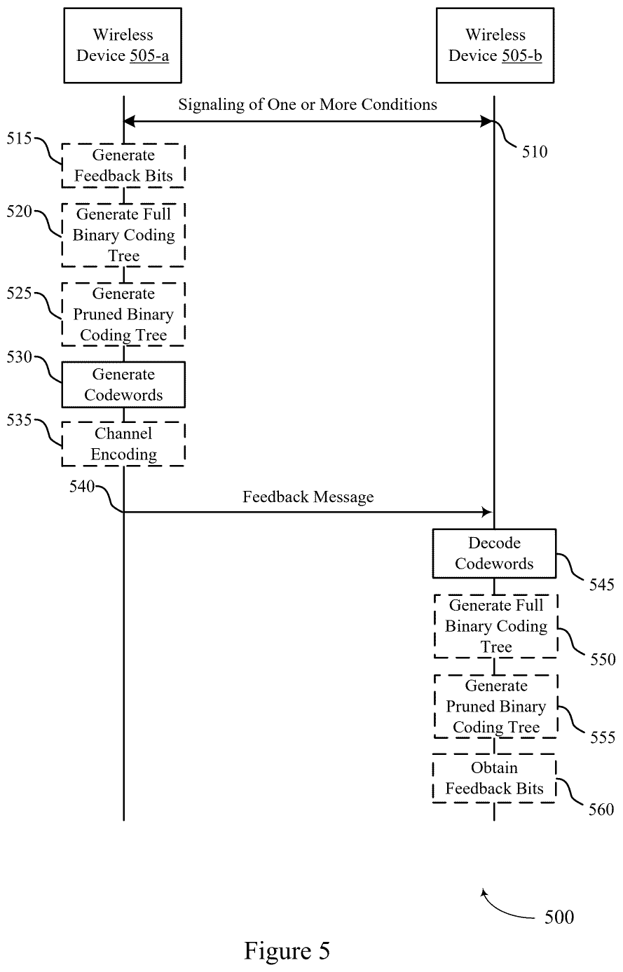

FIG. 5 shows an example of a process flow 500 that supports techniques for communicating HARQ feedback using pruned compression coding configurations (e.g. pruned Huffman coding configurations). The process flow 500 may implement or be implemented to realize aspects of the wireless communications system 100, the signaling configuration 200, and the binary coding tree diagrams 300 and 400. For example, the process flow 500 may illustrate an indication of conditions for generating a pruned binary coding tree (e.g., pruned Huffman tree) for encoding or decoding codewords between wireless devices 505, which may be examples of corresponding devices described herein, including with reference to FIGS. 1-4.

At signaling operation 510, a wireless device 505-a (e.g., first wireless device) may communicate, with a wireless device 505-b (e.g., a second wireless device), signaling that may indicate one or more conditions for a pruned compression coding configuration (e.g., a pruned Huffman tree, pruned Huffman coding). In accordance with the one or more conditions for the pruned compression coding configuration, one or more nodes of a full binary coding tree (e.g., a Huffman tree) may be replaced with multiple equiprobable bits to generate a pruned binary coding tree (e.g., pruned Huffman tree). In some cases, the one or more conditions for the pruned compression coding configuration may include a pruned binary coding tree depth, a maximum codeword length, a quantity of codeword length groups, a quantity of channel encoding steps, a quantity of channel decoding steps, or any combination thereof. In some cases, the pruned compression coding configuration may include a pruned Huffman coding configuration, and the full binary coding tree and the pruned binary coding tree may include a full Huffman coding tree and a pruned Huffman coding tree, respectively.

In some implementations, at operation 515, the wireless device 505-a may generate one or more feedback bits associated with a feedback message.

In some implementations, at operation 520, the wireless device 505-a may generate the full binary coding tree based on one or more feedback bits (e.g., the one or more feedback bits at 515) including IID bits, where the full binary coding tree may be generated in accordance with a probability associated with each bit of the one or more feedback bits. In other implementations, at operation 520, the wireless device 505-a may generate the full binary coding tree based on the one or more feedback bits including correlated feedback bits, where the full binary coding tree may be generated in accordance with a probability associated with each bit of the one or more feedback bits and in accordance with a correlation factor associated with the one or more feedback bits.

In some implementations, at operation 525, the wireless device 505-a may generate the pruned binary coding tree based on the full binary coding tree, as described at operation 520, and in accordance with the one or more conditions for the pruned compression coding configuration, as described at signaling operation 510. For example, the wireless device 505-a may replace one or more nodes of the full binary coding tree with multiple equiprobable bits in accordance with the one or more conditions. In some cases, in accordance with the one or more conditions for the pruned compression coding configuration, a first node of the one or more nodes of the full binary coding tree may be replaced with at least one codeword associated with at least a second node of the one or more nodes of the full binary coding tree to generate the pruned binary coding tree.

At operation 530, the wireless device 505-a may generate one or more codewords associated with the one or more feedback bits, as described at operation 515, in accordance with the pruned binary coding tree. In some cases, in accordance with the one or more conditions for the pruned compression coding configuration, a first maximum codeword length associated with the pruned binary coding tree may be shorter than a second maximum codeword length associated with the full binary coding tree. In some cases, in accordance with the one or more conditions for the pruned compression coding configuration, a first quantity of codeword length groups associated with the pruned binary coding tree may be less than a second quantity of codeword length groups associated with the full binary coding tree.

In some implementations, at encoding operation 535, the wireless device 505-a may channel encode a set of bits of the one or more codewords in accordance with one or more lengths of the one or more codewords. For example, the wireless device 505-a may perform some channel encoding (e.g., SSCC) on the one or more codewords, as described further with reference to FIGS. 3 and 4.

At signaling operation 540, the wireless device 505-a may transmit a feedback message (e.g., the feedback message at 515) to the wireless device 505-b based on channel encoding the one or more codewords, as described at encoding operation 535. In some implementations, at signaling operation 540, the wireless device 505-b may receive the feedback message comprising one or more encoded codewords.

At decoding operation 545, the wireless device 505-b may decode the one or more encoded codewords based at least in part on the pruned binary coding tree to obtain the one or more feedback bits of the feedback message, as described further at 550, 555, and 560, as well as with reference to FIGS. 3 and 4. In some cases, at decoding operation 545, the wireless device 505-b may channel decode a set of bits of the one or more encoded codewords in accordance with one or more lengths of the one or more encoded codewords.

In some implementations, at operation 550, the wireless device 505-b may generate the full binary coding tree based on the one or more feedback bits including IID bits, where the full binary coding tree may be generated in accordance with a probability associated with each bit of the one or more feedback bits. In other implementations, at operation 550, the wireless device 505-b may generate the full binary coding tree based on the one or more feedback bits including correlated feedback bits, where the full binary coding tree may be generated in accordance with a probability associated with each bit of the one or more feedback bits and in accordance with a correlation factor associated with the one or more feedback bits.

In some implementations, at process flow operation 555, the wireless device 505-b may generate the pruned binary coding tree based on the full binary coding tree, as described at operation 550, and in accordance with the one or more conditions for the pruned compression coding configuration, as described at signaling operation 510. For example, the wireless device 505-b may replace one or more nodes of the full binary coding tree with multiple equiprobable bits in accordance with the one or more conditions.

At process flow operation 560, the wireless device 505-b may obtain the one or more feedback bits of the feedback message in accordance with the one or more encoded codewords and the pruned binary coding tree.

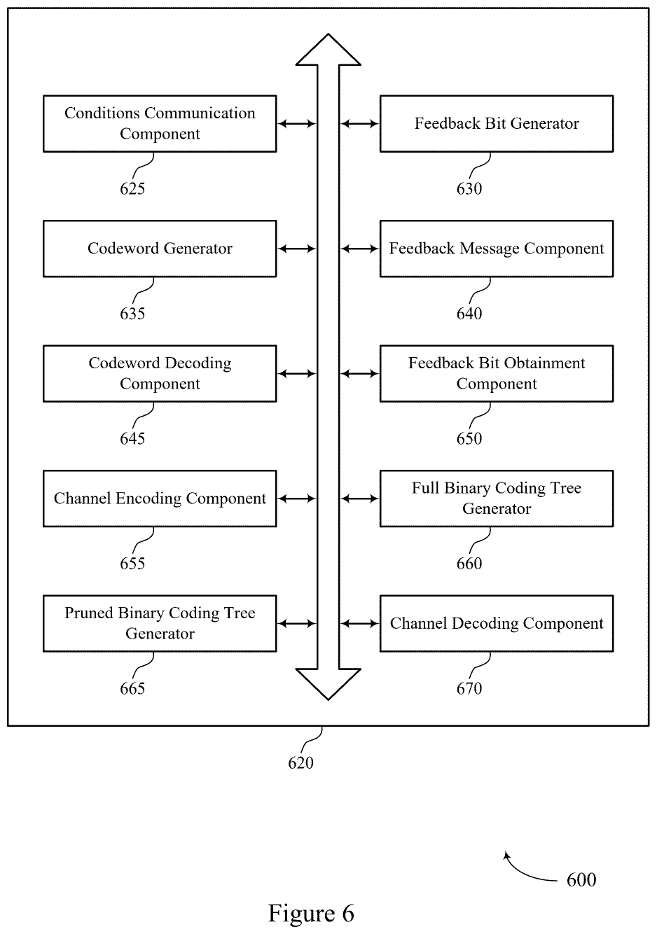

FIG. 6 shows an example of a processing system 620 that supports techniques for communicating HARQ feedback using pruned Huffman coding. A processing system 620 may be an example of a processing system 145 (such as network entity 105) and may include a conditions communication component 625, a feedback bit generator 630, a codeword generator 635, a feedback message component 640, a codeword decoding component 645, a feedback bit obtainment component 650, a channel encoding component 655, a full binary coding tree generator 660, a pruned binary coding tree generator 665, a channel decoding component 670, or any combination thereof. A processing system 620, or various component thereof, may be an example of means for performing (such as a means for causing a network entity 105 to perform) various techniques described herein.

The conditions communication component 625 may be configured to cause the UE 115 or the network entity 105 to communicate, with a second wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree. The codeword generator 635 may be configured to cause the UE 115 or the network entity 105 to generate one or more codewords based at least in part on one or more feedback bits in accordance with the pruned binary coding tree. The feedback message component 640 may be configured to cause the UE 115 or the network entity 105 to transmit a feedback message to the second wireless device based on channel encoding the one or more codewords.

In some examples, the feedback bit generator 630 may be configured to cause the UE 115 or the network entity 105 to generate the one or more feedback bits associated with the feedback message.

In some examples, the one or more conditions for the pruned compression coding configuration include a pruned binary coding tree depth, a maximum codeword length, a quantity of codeword length groups, a quantity of channel encoding steps, a quantity of channel decoding steps, or any combination thereof.

In some examples, in accordance with the one or more conditions for the pruned compression coding configuration, a first maximum codeword length associated with the pruned binary coding tree is shorter than a second maximum codeword length associated with the full binary coding tree. In some examples, in accordance with the one or more conditions for the pruned compression coding configuration, a first quantity of codeword length groups associated with the pruned binary coding tree is less than a second quantity of codeword length groups associated with the full binary coding tree.

In some examples, the pruned compression coding configuration includes a pruned Huffman coding configuration. In some examples, the full binary coding tree and the pruned binary coding tree include a full Huffman coding tree and a pruned Huffman coding tree, respectively.

In some examples, to support transmitting the feedback message, the channel encoding component 655 may be configured to cause the UE 115 or the network entity 105 to channel encode a set of bits of the one or more codewords in accordance with one or more lengths of the one or more codewords.

In some examples, the full binary coding tree generator 660 may be configured to cause the UE 115 or the network entity 105 to generate the full binary coding tree based on the one or more feedback bits including IID bits, and where the full binary coding tree is generated in accordance with a probability associated with each bit of the one or more feedback bits. In some examples, the pruned binary coding tree generator 665 may be configured to cause the UE 115 or the network entity 105 to generate the pruned binary coding tree based on the full binary coding tree and in accordance with the one or more conditions for the pruned compression coding configuration.

In some examples, the full binary coding tree generator 660 may be configured to cause the UE 115 or the network entity 105 to generate the full binary coding tree based on the one or more feedback bits including correlated feedback bits, and where the full binary coding tree is generated in accordance with a probability associated with each bit of the one or more feedback bits and in accordance with a correlation factor associated with the one or more feedback bits. In some examples, the pruned binary coding tree generator 665 may be configured to cause the UE 115 or the network entity 105 to generate the pruned binary coding tree based on the full binary coding tree and in accordance with the one or more conditions for the pruned compression coding configuration.

In some examples, in accordance with the one or more conditions for the pruned compression coding configuration, a first node of the one or more nodes of the full binary coding tree is replaced with at least one codeword associated with at least a second node of the one or more nodes of the full binary coding tree to generate the pruned binary coding tree.

In some examples, the conditions communication component 625 may be configured to cause the UE 115 or the network entity 105 to communicate, with a first wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree. In some examples, the feedback message component 640 may be configured to cause the UE 115 or the network entity 105 to receive a feedback message including one or more encoded codewords. The codeword decoding component 645 may be configured to cause the UE 115 or the network entity 105 to decode the one or more encoded codewords based on the pruned binary coding tree to obtain one or more feedback bits of the feedback message.

In some examples, the feedback bit obtainment component 650 may be configured to cause the UE 115 or the network entity 105 to obtain the one or more feedback bits of the feedback message in accordance with the one or more encoded codewords and the pruned binary coding tree.

In some examples, the one or more conditions for the pruned compression coding configuration include a pruned binary coding tree depth, a maximum codeword length, a quantity of codeword length groups, a quantity of channel encoding steps, a quantity of channel decoding steps, or any combination thereof.

In some examples, in accordance with the one or more conditions for the pruned compression coding configuration, a first maximum codeword length associated with the pruned binary coding tree is shorter than a second maximum codeword length associated with the full binary coding tree. In some examples, in accordance with the one or more conditions for the pruned compression coding configuration, a first quantity of codeword length groups associated with the pruned binary coding tree is less than a second quantity of codeword length groups associated with the full binary coding tree.

In some examples, the pruned compression coding configuration includes a pruned Huffman coding configuration. In some examples, the full binary coding tree and the pruned binary coding tree include a full Huffman coding tree and a pruned Huffman coding tree, respectively.

In some examples, to support channel decoding the one or more encoded codewords, the channel decoding component 670 may be configured to cause the UE 115 or the network entity 105 to channel decode a set of bits of the one or more encoded codewords in accordance with one or more lengths of the one or more encoded codewords.

In some examples, the full binary coding tree generator 660 may be configured to cause the UE 115 or the network entity 105 to generate the full binary coding tree based on the one or more feedback bits including IID bits, and where the full binary coding tree is generated in accordance with a probability associated with each bit of the one or more feedback bits. In some examples, the pruned binary coding tree generator 665 may be configured to cause the UE 115 or the network entity 105 to generate the pruned binary coding tree based on the full binary coding tree and in accordance with the one or more conditions for the pruned compression coding configuration.

In some examples, the full binary coding tree generator 660 may be configured to cause the UE 115 or the network entity 105 to generate the full binary coding tree based on the one or more feedback bits including correlated feedback bits, and where the full binary coding tree is generated in accordance with a probability associated with each bit of the one or more feedback bits and in accordance with a correlation factor associated with the one or more feedback bits. In some examples, the pruned binary coding tree generator 665 may be configured to cause the UE 115 or the network entity 105 to generate the pruned binary coding tree based on the full binary coding tree and in accordance with the one or more conditions for the pruned compression coding configuration.

In some examples, in accordance with the one or more conditions for the pruned compression coding configuration, a first node of the one or more nodes of the full binary coding tree is replaced with at least one codeword associated with at least a second node of the one or more nodes of the full binary coding tree to generate the pruned binary coding tree.

By including or configuring a processing system 620 for operation in a processing system 620 as described herein, the processing system 620 may support techniques for reduced processing, reduced power consumption, and more efficient utilization of communication resources.

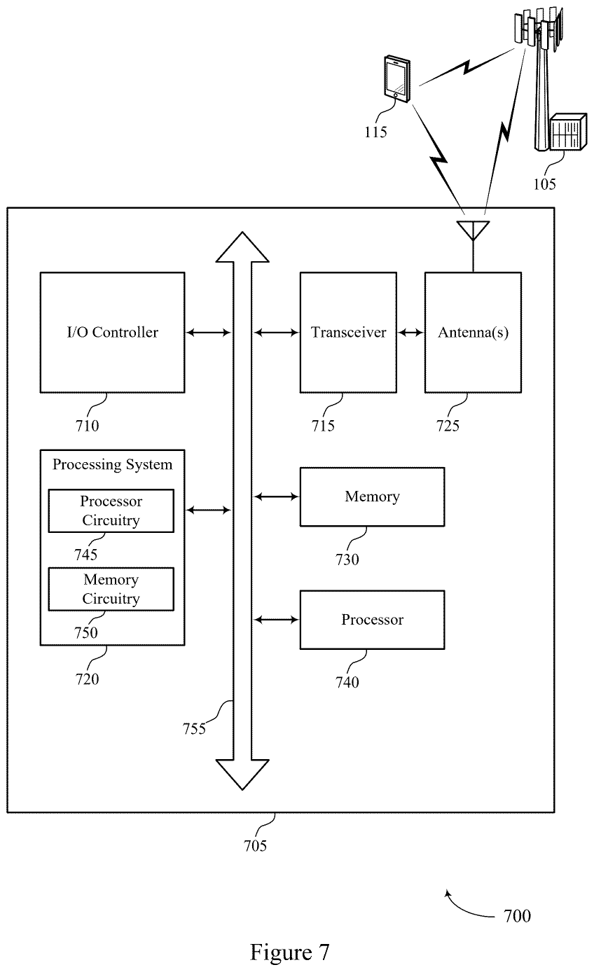

FIG. 7 shows an example of a system 700 including a device 705 that supports techniques for communicating HARQ feedback using pruned Huffman coding. The device 705 may be an example of or include components of UE 115. The device 705 may communicate (such as wirelessly) with one or more other devices (such as network entities 105, UEs 115). The device 705 may include components for transmitting and receiving communication, which may include a processing system 720, an input/output (I/O) controller, such as an I/O controller 710, a transceiver 715, antenna(s) 725, a memory 730, and a processor 740. Components of the device 705 may be coupled (such as operatively, communicatively, functionally, electronically, electrically, in electronic communication) a bus 755.

The transceiver 715 may support bi-directional communication via antenna(s) 725, and may support transmission operations, reception operations, or both, as described herein. The transceiver 715 may implement functionality of a modem (such as a wireless modem) and may include one or more RF chains. An RF chain may include one or more filters, mixers, oscillators, amplifiers, analog-to-digital converters (ADCs), and other components that convert between an analog signal (such as for transmission or reception via an air interface) and a digital signal (such as for digital processing at the device 705). The transceiver 715 may modulate symbols and provide the modulated symbols to antenna(s) 725 for transmission, and demodulate symbols from signals received using antenna(s) 725.

The processor 740 may be a general-purpose processing component that supports various operations (such as applications) of the device 705. The memory 730 may be a general-purpose storage component that stores code executable by the processor 740. Such code may include instructions that, when executed by the processor 740, cause the device 705 to perform various functions (such as to support an application of the device 705). The I/O controller 710 may manage inputs and outputs for the device 705, may manage peripherals not integrated into the device 705, or may represent a physical connection (such as port) to an external peripheral. The processor 740 may interact with a modem, a keyboard, a mouse, a touchscreen, or other device (such as via I/O controller 710). In some implementations, a user may interact with the device 705 via the I/O controller 710 or via hardware components controlled by the I/O controller 710.

The processing system 720 may be an example of a processing system 140 or a processing system 600. For example, the processing system 720 may include processor circuitry 745 and memory circuitry 750 that stores code, and may be configured to cause the device 705 to perform operations that support techniques for communicating HARQ feedback using pruned Huffman coding. Although the processing system 720 is illustrated as a separate component, which may involve a separate chip, chipset, or other module, in some implementations, one or more functions described with reference to the processing system 720 may be supported by or performed by a transceiver 715, antenna(s) 725, a processor 740, memory 730, or any combination thereof, such that a processing system 720 may include one or more of a transceiver 715, antenna(s) 725, a processor 740, memory 730, or any combination thereof.

By including or configuring the processing system 720 for operation in the device 705 as described herein, may support techniques for improved communication reliability, reduced latency, improved user experience related to reduced processing, reduced power consumption, and more efficient utilization of communication resources.

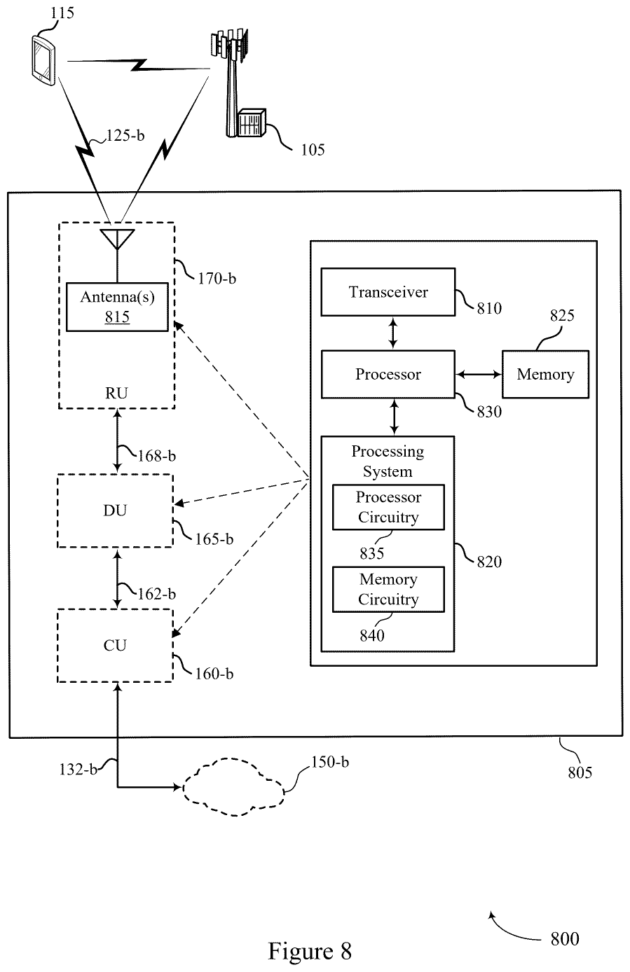

FIG. 8 shows an example of a system 800 including a device 805 that supports techniques for communicating HARQ feedback using pruned Huffman coding. The device 805 may communicate (such as via one or more wired interfaces or one or more wireless interfaces) with other network devices or network equipment such as a core network 150-b, other network entities 105, UEs 115, or any combination thereof. The device 805 may include components for transmitting and receiving communication, which may include a processing system 820, a transceiver 810, antenna(s) 815, a memory 825, and a processor 830. Components of the device 805 may be coupled (such as operatively, communicatively, functionally, electronically, electrically, in electronic communication) via one or more interfaces.

The transceiver 810 may communicate bi-directionally with another transceiver via wired or wireless links, and may support transmission operations, reception operations, or both, as described herein. The transceiver 810 may include a modem to modulate and demodulate signals, to provide the modulated signals for transmission (such as via antenna(s) 815, via a wired interface), and to demodulate received signals (such as received via antenna(s) 815, received via a wired interface). The transceiver 810 may be operable to support communication via one or more communication links (such as a communication link 125-b, a backhaul link 132-b, a midhaul link 162-b, fronthaul link 168-b).

The processor 830 may be a general-purpose processing component that supports various operations (such as applications) of the device 805. The memory 825 may be a general-purpose storage component that stores code executable by the processor 830. Such code may include instructions that, when executed by the processor 830, cause the device 805 to perform various functions (such as to support an application of the device 805).

For examples in which the device 805 is a network entity 105 in a disaggregated architecture, one or more components of the device 805 may be located at one or more of a CU 160-b, a DU 165-b, or an RU 170-b, one or more of which may include aspects of the processing system 820, the processor 830, the memory 825, or the transceiver 810. Functions of the device 805 may be performed at different components or an operation may be divided between different components (such as different functions being supported by aspects of the CU 160-b, the DU 165-b, or the RU 170-b, the transceiver 810, the processor 830, the memory 825, the processing system 820, or any combination thereof). For example, the processing system 820 may be a component of one or more of the CU 160-b, the DU 165-b, or the RU 170-b. In some examples, interfaces between components of device 805 (such as CU 160-b, DU 165-b, RU 170-b) may support communication at a protocol layer or between protocol layers of a protocol stack.

In some examples, the processing system 820 may manage aspects of communication with the core network 150-b (such as via a backhaul link 132). For example, the processing system 820 may manage the transfer of data communication for UEs 115 with a gateway of the core network 150-b. In some examples, the processing system 820 may manage communication with one or more other network entities 105 and may include a controller or scheduler for controlling communication with UEs 115 (such as in cooperation with the one or more other network entities 105). In some examples, the processing system 820 may support an interface (such as X2 interface, Xn interface) to provide communication between network entities 105.

The processing system 820 may be an example of a processing system 145 or a processing system 600. For example, the processing system 820 may include processor circuitry 835 and memory circuitry 840 that stores code, and the processing system 820 may be configured to cause the device 805 to perform operations that support techniques for communicating HARQ feedback using pruned Huffman coding. Although the processing system 820 is illustrated as a separate component, which may involve a separate chip, chipset, or other module, in some implementations, one or more functions described with reference to the processing system 820 may be supported by or performed by a transceiver 810, antenna(s) 815, a processor 830, memory 825, or any combination thereof, such that a processing system 820 may include one or more of a transceiver 810, antenna(s) 815, a processor 830, memory 825, or any combination thereof. Further, processor circuitry 835 and memory circuitry 840 each may be implemented at the device 805 in accordance with an aggregated architecture, or the processor circuitry 835 and the memory circuitry 840 may be implemented at one or more of a CU 160-b, a DU 165-b, or an RU 170-b in accordance with a disaggregated architecture.

By including or configuring the processing system 820 for operation in the device 805 as described herein, may support techniques for improved communication reliability, reduced latency, improved user experience related to reduced processing, reduced power consumption, and more efficient utilization of communication resources.

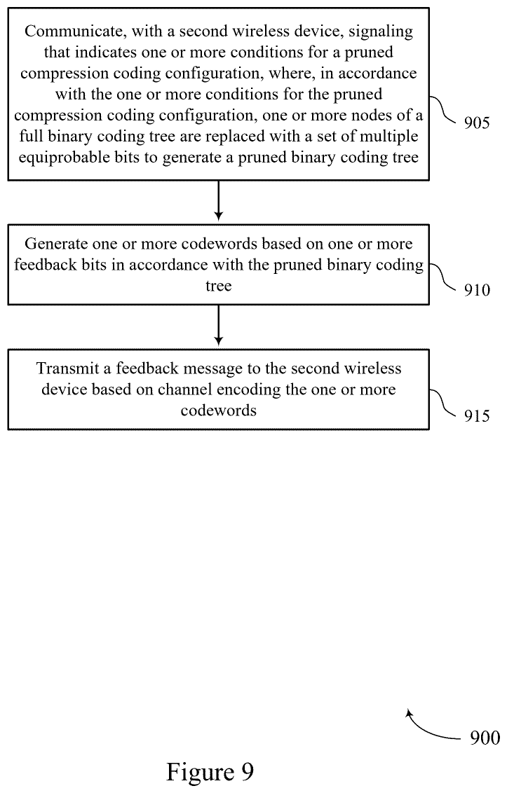

FIG. 9 shows an example of a method 900 that supports techniques for communicating HARQ feedback using pruned Huffman coding. Operations of the method 900 may be performed by a UE 115 or a network entity 105 or respective components (such as using a processing system configured to cause the respective device to perform one or more of the operations), as described herein.

At 905, the method may include communicating, with a second wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree. In some examples, aspects of the operations of 905 may be performed by a conditions communication component 625.

At 910, the method may include generating one or more codewords based at least in part on one or more feedback bits in accordance with the pruned binary coding tree. In some examples, aspects of the operations of 915 may be performed by a codeword generator 635.

At 915, the method may include transmitting a feedback message to the second wireless device based on channel encoding the one or more codewords. In some examples, aspects of the operations of 920 may be performed by a feedback message component 640.

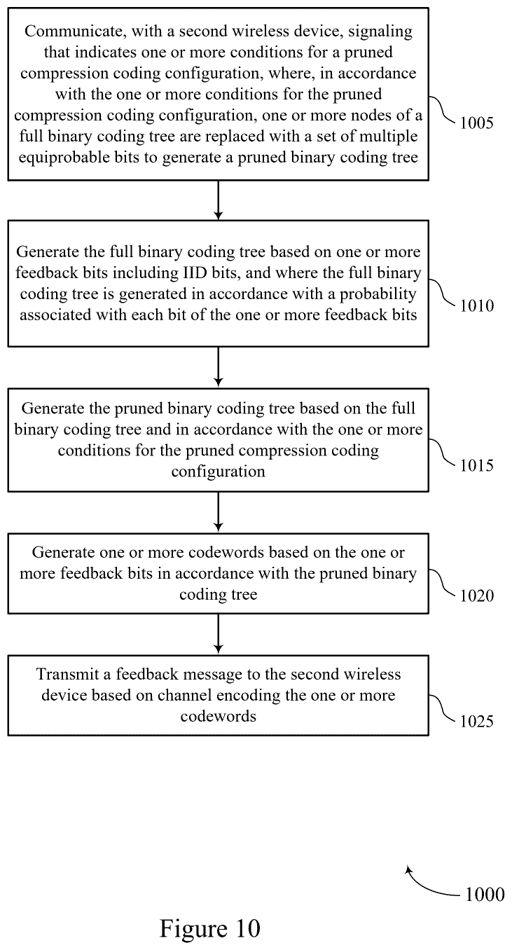

FIG. 10 shows an example of a method 1000 that supports techniques for communicating HARQ feedback using pruned Huffman coding. Operations of the method 1000 may be performed by a UE 115 or a network entity 105 or respective components (such as using a processing system configured to cause the respective device to perform one or more of the operations), as described herein.

At 1005, the method may include communicating, with a second wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree. In some examples, aspects of the operations of 1005 may be performed by a conditions communication component 625.

At 1010, the method may include generating the full binary coding tree based on one or more feedback bits including IID bits, and where the full binary coding tree is generated in accordance with a probability associated with each bit of the one or more feedback bits. In some examples, aspects of the operations of 1015 may be performed by a full binary coding tree generator 660.

At 1015, the method may include generating the pruned binary coding tree based on the full binary coding tree and in accordance with the one or more conditions for the pruned compression coding configuration. In some examples, aspects of the operations of 1020 may be performed by a pruned binary coding tree generator 665.

At 1020, the method may include generating one or more codewords based on the one or more feedback bits in accordance with the pruned binary coding tree. In some examples, aspects of the operations of 1025 may be performed by a codeword generator 635.

At 1025, the method may include transmitting a feedback message to the second wireless device based on channel encoding the one or more codewords. In some examples, aspects of the operations of 1030 may be performed by a feedback message component 640.

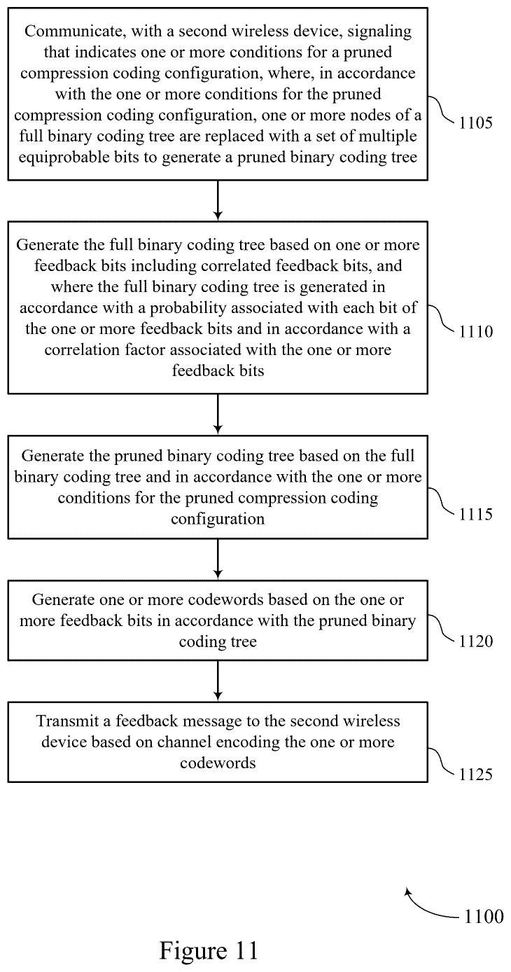

FIG. 11 shows an example of a method 1100 that supports techniques for communicating HARQ feedback using pruned Huffman coding. Operations of the method 1100 may be performed by a UE 115 or a network entity 105 or respective components (such as using a processing system configured to cause the respective device to perform one or more of the operations), as described herein.

At 1105, the method may include communicating, with a second wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree. In some examples, aspects of the operations of 1105 may be performed by a conditions communication component 625.

At 1110, the method may include generating the full binary coding tree based on one or more feedback bits including correlated feedback bits, and where the full binary coding tree is generated in accordance with a probability associated with each bit of the one or more feedback bits and in accordance with a correlation factor associated with the one or more feedback bits. In some examples, aspects of the operations of 1115 may be performed by a full binary coding tree generator 660.

At 1115, the method may include generating the pruned binary coding tree based on the full binary coding tree and in accordance with the one or more conditions for the pruned compression coding configuration. In some examples, aspects of the operations of 1120 may be performed by a pruned binary coding tree generator 665.

At 1120, the method may include generating one or more codewords based on the one or more feedback bits in accordance with the pruned binary coding tree. In some examples, aspects of the operations of 1125 may be performed by a codeword generator 635.

At 1125, the method may include transmitting a feedback message to the second wireless device based on channel encoding the one or more codewords. In some examples, aspects of the operations of 1130 may be performed by a feedback message component 640.

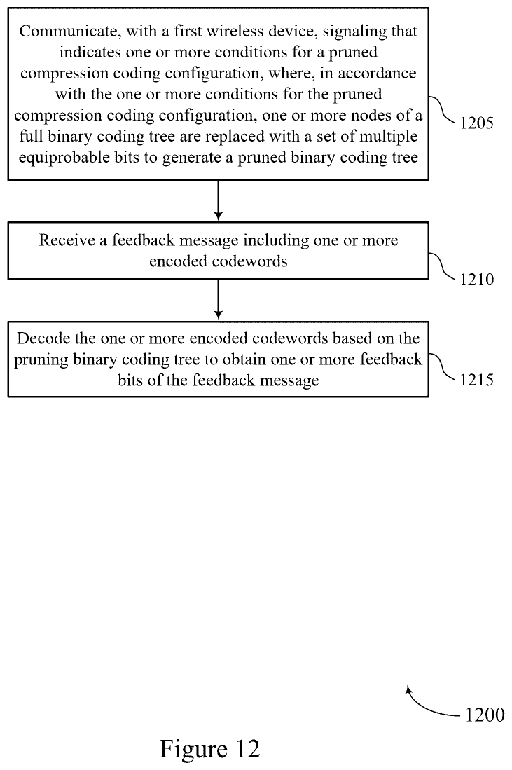

FIG. 12 shows an example of a method 1200 that supports techniques for communicating HARQ feedback using pruned Huffman coding. Operations of the method 1200 may be performed by a UE 115 or a network entity 105 or respective components (such as using a processing system configured to cause the respective device to perform one or more of the operations), as described herein.

At 1205, the method may include communicating, with a first wireless device, signaling that indicates one or more conditions for a pruned compression coding configuration, where, in accordance with the one or more conditions for the pruned compression coding configuration, one or more nodes of a full binary coding tree are replaced with a set of multiple equiprobable bits to generate a pruned binary coding tree. In some examples, aspects of the operations of 1205 may be performed by a conditions communication component 625.

At 1210, the method may include receiving a feedback message including one or more encoded codewords. In some examples, aspects of the operations of 1210 may be performed by a feedback message component 640.

At 1215, the method may include decoding the one or more encoded codewords based on the pruned binary coding tree to obtain one or more feedback bits of the feedback message. In some examples, aspects of the operations of 1215 may be performed by a codeword decoding component 645.

Implementation examples are described in the following numbered clauses:

Aspect 1: A method for wireless communications at a first wireless device, comprising: communicating, with a second wireless device, signaling that indicates one or more conditions for a pruned compression coding configuration, wherein, in accordance with the one or more conditions for the pruned compression coding configuration, one or more nodes of a full binary coding tree are replaced with a plurality of equiprobable bits to generate a pruned binary coding tree; generating one or more codewords based at least in part on one or more feedback bits in accordance with the pruned binary coding tree; and transmitting a feedback message to the second wireless device based at least in part on channel encoding the one or more codewords.

Aspect 2: The method of aspect 1, wherein the one or more conditions for the pruned compression coding configuration comprise a pruned binary coding tree depth, a maximum codeword length, a quantity of codeword length groups, a quantity of channel encoding steps, a quantity of channel decoding steps, or any combination thereof.

Aspect 3: The method of any of aspects 1 through 2, wherein in accordance with the one or more conditions for the pruned compression coding configuration, a first maximum codeword length associated with the pruned binary coding tree is shorter than a second maximum codeword length associated with the full binary coding tree, and in accordance with the one or more conditions for the pruned compression coding configuration, a first quantity of codeword length groups associated with the pruned binary coding tree is less than a second quantity of codeword length groups associated with the full binary coding tree.

Aspect 4: The method of any of aspects 1 through 3, wherein the pruned compression coding configuration comprises a pruned Huffman coding configuration, and the full binary coding tree and the pruned binary coding tree comprise a full Huffman coding tree and a pruned Huffman coding tree, respectively.

Aspect 5: The method of any of aspects 1 through 4, wherein transmitting the feedback message comprises: channel encoding a set of bits of the one or more codewords in accordance with one or more lengths of the one or more codewords.

Aspect 6: The method of any of aspects 1 through 5, further comprising: generating the full binary coding tree based at least in part on the one or more feedback bits comprising IID bits, and wherein the full binary coding tree is generated in accordance with a probability associated with each bit of the one or more feedback bits; and generating the pruned binary coding tree based at least in part on the full binary coding tree and in accordance with the one or more conditions for the pruned compression coding configuration.

Aspect 7: The method of any of aspects 1 through 5, further comprising: generating the full binary coding tree based at least in part on the one or more feedback bits comprising correlated feedback bits, and wherein the full binary coding tree is generated in accordance with a probability associated with each bit of the one or more feedback bits and in accordance with a correlation factor associated with the one or more feedback bits; and generating the pruned binary coding tree based at least in part on the full binary coding tree and in accordance with the one or more conditions for the pruned compression coding configuration.

Aspect 8: The method of any of aspects 1 through 7, wherein in accordance with the one or more conditions for the pruned compression coding configuration, a first node of the one or more nodes of the full binary coding tree is replaced with at least one codeword associated with at least a second node of the one or more nodes of the full binary coding tree to generate the pruned binary coding tree.

Aspect 9: A method for wireless communications at a second wireless device, comprising: communicating, with a first wireless device, signaling that indicates one or more conditions for a pruned compression coding configuration, wherein, in accordance with the one or more conditions for the pruned compression coding configuration, one or more nodes of a full binary coding tree are replaced with a plurality of equiprobable bits to generate a pruned binary coding tree; receiving a feedback message comprising one or more encoded codewords; decoding the one or more encoded codewords based at least in part on the pruned binary coding tree to obtain one or more feedback bits of the feedback message.

Aspect 10: The method of aspect 9, wherein the one or more conditions for the pruned compression coding configuration comprise a pruned binary coding tree depth, a maximum codeword length, a quantity of codeword length groups, a quantity of channel encoding steps, a quantity of channel decoding steps, or any combination thereof.

Aspect 11: The method of any of aspects 9 through 10, wherein in accordance with the one or more conditions for the pruned compression coding configuration, a first maximum codeword length associated with the pruned binary coding tree is shorter than a second maximum codeword length associated with the full binary coding tree, and in accordance with the one or more conditions for the pruned compression coding configuration, a first quantity of codeword length groups associated with the pruned binary coding tree is less than a second quantity of codeword length groups associated with the full binary coding tree.

Aspect 12: The method of any of aspects 9 through 11, wherein the pruned compression coding configuration comprises a pruned Huffman coding configuration, and the full binary coding tree and the pruned binary coding tree comprise a full Huffman coding tree and a pruned Huffman coding tree, respectively.

Aspect 13: The method of any of aspects 9 through 12, wherein channel decoding the one or more encoded codewords comprises: channel decoding a set of bits of the one or more encoded codewords in accordance with one or more lengths of the one or more encoded codewords.

Aspect 14: The method of any of aspects 9 through 13, further comprising: generating the full binary coding tree based at least in part on the one or more feedback bits comprising IID bits, and wherein the full binary coding tree is generated in accordance with a probability associated with each bit of the one or more feedback bits; and generating the pruned binary coding tree based at least in part on the full binary coding tree and in accordance with the one or more conditions for the pruned compression coding configuration.

Aspect 15: The method of any of aspects 9 through 13, further comprising: generating the full binary coding tree based at least in part on the one or more feedback bits comprising correlated feedback bits, and wherein the full binary coding tree is generated in accordance with a probability associated with each bit of the one or more feedback bits and in accordance with a correlation factor associated with the one or more feedback bits; and generating the pruned binary coding tree based at least in part on the full binary coding tree and in accordance with the one or more conditions for the pruned compression coding configuration.

Aspect 16: The method of any of aspects 9 through 15, wherein in accordance with the one or more conditions for the pruned compression coding configuration, a first node of the one or more nodes of the full binary coding tree is replaced with at least one codeword associated with at least a second node of the one or more nodes of the full binary coding tree to generate the pruned binary coding tree.

Aspect 17: A first wireless device for wireless communications, comprising a processing system that includes processor circuitry and memory circuitry that stores code, the processing system configured to cause the first wireless device to perform a method of any of aspects 1 through 8.

Aspect 18: A first wireless device for wireless communications, comprising at least one means for performing a method of any of aspects 1 through 8.

Aspect 19: A non-transitory computer-readable medium storing code for wireless communications, the code comprising instructions executable by one or more processors to perform a method of any of aspects 1 through 8.

Aspect 20: A second wireless device for wireless communications, comprising a processing system that includes processor circuitry and memory circuitry that stores code, the processing system configured to cause the second wireless device to perform a method of any of aspects 9 through 16.

Aspect 21: A second wireless device for wireless communications, comprising at least one means for performing a method of any of aspects 9 through 16.

Aspect 22: A non-transitory computer-readable medium storing code for wireless communications, the code comprising instructions executable by one or more processors to perform a method of any of aspects 9 through 16.

It should be noted that methods described herein describe possible implementations. Other implementations in accordance with the described techniques are possible, including implementations in which operations are rearranged or otherwise modified relative to the described methods. Further, aspects from two or more of the described methods may be combined.

Although aspects of 5G or 6G systems may be described for purposes of example and corresponding terminology may be used in the description, the techniques described herein are applicable beyond 5G, or 6G networks. For example, the described techniques may be applicable to other communication systems such as Institute of Electrical and Electronics Engineers (IEEE) 802.11 (Wi-Fi), IEEE 802.20, Flash-OFDM, or other systems and radio technologies not explicitly mentioned herein.

As used herein, a processing system (such as a processing system 140, a processing system 145) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform functions or operations described herein. A group of processors collectively configurable or configured to cause a device to perform a set of functions may include a first processor configured to cause the device to perform a first function of the set and a second processor configured to cause the device to perform a second function of the set. In some other examples, each of a group of processors may be configured to cause a device to perform a same set of functions.

As used herein, a processing system (such as a processing system 140, a processing system 145) also includes memory circuitry in the form of one or multiple memory devices, memory blocks, memory elements, or other discrete gate or transistor logic or circuitry, each of which may include or implement tangible storage media such as random-access memory (RAM) or read-only memory (ROM), or combinations thereof (any one or more of which may be generally referred to herein individually as a “memory” or collectively as “the memory” or “the memory circuitry”). One or more of the memories may be coupled (such as operatively, communicatively, electronically, electrically) with one or more processors of the processor circuitry and may individually or collectively store processor-executable code or instructions (such as software) that, when executed by one or more of the processors, may cause a device (such as configure the device, using one or more of the processors) to perform functions or operations described herein. Additionally, or alternatively, in some examples, one or more of the processors may be configured to cause a device to perform functions or operations described herein without requiring configuration by software. As used herein, “software” shall be construed to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

As used herein, a processing system (such as a processing system 140, a processing system 145) may include or be coupled with one or more modems (such as a cellular modem, a 5G-compliant modem, a 6G-compliant modem). In some examples, one or more processors of a processing system may include or implement one or more of the modems. A processing system also may include or be coupled with multiple radios (collectively “the radio”), multiple RF chains, or multiple transceivers, each of which may in turn be coupled with one or more of multiple antennas. In some examples, one or more processors of a processing system may include or implement one or more of the radios, RF chains, or transceivers. An RF chain may include one or more filters, mixers, oscillators, amplifiers, analog-to-digital converters (ADCs), or other devices that convert between an analog signal (such as for transmission or reception via an air interface) and a digital signal (such as for processing by processor circuitry).

As described herein, being “configured to,” being “configurable to,” and being “operable to” may be used interchangeably and may be associated with a capability, when executing code (such as processor-executable code, instructions) stored in memory circuitry (such as a non-transitory computer-readable medium, of the memory circuitry, storing code for wireless communication that is executable by a processing system) or otherwise, to perform one or more of the functions described herein.

As used herein, the term “determine” or “determining” can encompass one or more of a variety of actions. For example, “determining” can include one or more of calculating, computing, processing, deriving, detecting, estimating, looking up, inferring, ascertaining, measuring, resolving, selecting, obtaining, identifying, interpreting, demodulating, decoding, reading, establishing, forming, or generating, among other examples. In some such examples, determining can involve a processing system performing some type of calculating, computing, deriving, estimating, inferring, ascertaining, resolving, predicting, or other processing to obtain one or more numerical values, sets, elements, or other information or results. In some such examples, determining can involve a processing system identifying, looking up, investigating or otherwise obtaining some type of value, set, element, or other information or result from a table, data structure, database, or an implementation of memory, such as from a larger set of values, sets, or elements or other information or results. In some such examples, determining can involve a processing system identifying, interpreting, demodulating, decoding, detecting, reading, or otherwise obtaining some type of value, set, element, or other information or result signaled in, for example, a received wireless signal. In some such examples, determining can involve a processing system performing a measurement, such as on a received signal.

As used herein, the phrase “associated with” is intended to be interpreted in the inclusive sense, unless otherwise explicitly indicated. For example, the phrase “associated with” is not to be construed as a reference to a closed set of conditions, factors, criteria, elements, components or actions, among other examples. Specifically, unless a phrase refers to “associated with only ‘a,’” or the equivalent in context, whatever it is that is “associated with ‘a,’” may be associated with “a” alone or associated with a combination of “a” and one or more other conditions, factors, criteria, elements, components or actions, among other examples. The phrase “associated with” may be interpreted to mean or be interchanged with “in association with,” “in accordance with,” “based on,” “based at least in part on,” “as a function of,” “in response to,” “responsive to,” “using,” “coupled with,” in communication with,” “configured with,” “included with,” or “in cooperation with,” as appropriate in the relevant context unless otherwise explicitly indicated. Additionally, the use of such phrases does not indicate that what follows the phrase is the focal point or primary factor associated with the limitation preceding the phrase.

As used herein, a phrase referring to “at least one of” or “one or more of” a list of items refers to any combination of those items, including single members. For example, “at least one of: a, b, or c” is intended to cover: a, b, c, a-b, a-c, b-c, and a-b-c. Additionally, as used herein, a phrase referring to “a” or “an” element refers to one or more of such elements acting individually or collectively to perform the recited function(s). Thus, the terms “a,” “at least one,” “one or more,” and “at least one of one or more” may be interchangeable. For instance, for a claim that refers to “a” component performing one or more functions, each of the individual functions may be performed by a single component or by any combination of multiple components, and subsequent reference to a component introduced with the article “a” using the term “the” may refer to any or all of the single or multiple components. Thus, a component introduced with the article “a” may be understood to mean “one or more” components, and referring to “the” component subsequently in the claims may be understood to be equivalent to referring to “at least one of the one or more” components. Additionally, as used herein, a “set” can refer to one or more items, and a “subset” can refer to a whole set or less than the whole set, but not an empty set. Additionally, as used herein, the term “or” is intended to be interpreted in the inclusive sense, such as when referring to a series, and may be used interchangeably with the term “and/or,” unless otherwise explicitly indicated (for example, if used in conjunction with “either” or “only one of”). For example, “a or b” may include a only, b only, or a combination of a and b.

The disclosure is provided to enable a person having ordinary skill in the art to implement the described techniques. Modifications to the disclosure will be apparent to a person having ordinary skill in the art, and the techniques disclosed herein may be applied with other variations without departing from the scope of the disclosure. Thus, the disclosure is not limited to the examples and designs described herein but is to be accorded the broadest scope consistent with the principles and novel features disclosed herein.

What is claimed is:

1. A first wireless device, comprising:
one or more memories storing processor-executable code; and
one or more processors coupled with the one or more memories and individually or collectively operable to execute the code to cause the first wireless device to:
communicate, with a second wireless device, signaling that indicates one or more conditions for a pruned compression coding configuration, wherein, in accordance with the one or more conditions for the pruned compression coding configuration, one or more nodes of a full binary coding tree are replaced with a plurality of equiprobable bits to generate a pruned binary coding tree;
generate one or more codewords based at least in part on one or more feedback bits in accordance with the pruned binary coding tree; and
transmit a feedback message to the second wireless device based at least in part on channel encoding the one or more codewords.

2. The first wireless device of claim 1, wherein the one or more conditions for the pruned compression coding configuration comprise a pruned binary coding tree depth, a maximum codeword length, a quantity of codeword length groups, a quantity of channel encoding steps, a quantity of channel decoding steps, or any combination thereof.

3. The first wireless device of claim 1, wherein, in accordance with the one or more conditions for the pruned compression coding configuration, a first maximum codeword length associated with the pruned binary coding tree is shorter than a second maximum codeword length associated with the full binary coding tree, and
in accordance with the one or more conditions for the pruned compression coding configuration, a first quantity of codeword length groups associated with the pruned binary coding tree is less than a second quantity of codeword length groups associated with the full binary coding tree.

4. The first wireless device of claim 1, wherein the pruned compression coding configuration comprises a pruned Huffman coding configuration, and wherein the full binary coding tree and the pruned binary coding tree comprise a full Huffman coding tree and a pruned Huffman coding tree, respectively.

5. The first wireless device of claim 1, wherein, to transmit the feedback message, the one or more processors are individually or collectively operable to execute the code to cause the first wireless device to:
channel encode a set of bits of the one or more codewords in accordance with one or more lengths of the one or more codewords.

6. The first wireless device of claim 1, wherein the one or more processors are individually or collectively further operable to execute the code to cause the first wireless device to:
generate the full binary coding tree based at least in part on the one or more feedback bits comprising independent and identically distributed bits, and wherein the full binary coding tree is generated in accordance with a probability associated with each bit of the one or more feedback bits; and
generate the pruned binary coding tree based at least in part on the full binary coding tree and in accordance with the one or more conditions for the pruned compression coding configuration.

7. The first wireless device of claim 1, wherein the one or more processors are individually or collectively further operable to execute the code to cause the first wireless device to:
generate the full binary coding tree based at least in part on the one or more feedback bits comprising correlated feedback bits, and wherein the full binary coding tree is generated in accordance with a probability associated with each bit of the one or more feedback bits and in accordance with a correlation factor associated with the one or more feedback bits; and
generate the pruned binary coding tree based at least in part on the full binary coding tree and in accordance with the one or more conditions for the pruned compression coding configuration.

8. The first wireless device of claim 1, wherein in accordance with the one or more conditions for the pruned compression coding configuration, a first node of the one or more nodes of the full binary coding tree is replaced with at least one codeword associated with at least a second node of the one or more nodes of the full binary coding tree to generate the pruned binary coding tree.

9. A second wireless device, comprising:
one or more memories storing processor-executable code; and
one or more processors coupled with the one or more memories and individually or collectively operable to execute the code to cause the second wireless device to:
communicate, with a first wireless device, signaling that indicates one or more conditions for a pruned compression coding configuration, wherein, in accordance with the one or more conditions for the pruned compression coding configuration, one or more nodes of a full binary coding tree are replaced with a plurality of equiprobable bits to generate a pruned binary coding tree;
receive a feedback message comprising one or more encoded codewords; and
decode the one or more encoded codewords based at least in part on the pruned binary coding tree to obtain one or more feedback bits of the feedback message.

10. The second wireless device of claim 9, wherein the one or more conditions for the pruned compression coding configuration comprise a pruned binary coding tree depth, a maximum codeword length, a quantity of codeword length groups, a quantity of channel encoding steps, a quantity of channel decoding steps, or any combination thereof.

11. The second wireless device of claim 9, wherein, in accordance with the one or more conditions for the pruned compression coding configuration, a first maximum codeword length associated with the pruned binary coding tree is shorter than a second maximum codeword length associated with the full binary coding tree, and
in accordance with the one or more conditions for the pruned compression coding configuration, a first quantity of codeword length groups associated with the pruned binary coding tree is less than a second quantity of codeword length groups associated with the full binary coding tree.

12. The second wireless device of claim 9, wherein the pruned compression coding configuration comprises a pruned Huffman coding configuration, and wherein the full binary coding tree and the pruned binary coding tree comprise a full Huffman coding tree and a pruned Huffman coding tree, respectively.

13. The second wireless device of claim 9, wherein, to channel decode the one or more encoded codewords, the one or more processors are individually or collectively operable to execute the code to cause the second wireless device to:
channel decode a set of bits of the one or more encoded codewords in accordance with one or more lengths of the one or more encoded codewords.

14. The second wireless device of claim 9, wherein the one or more processors are individually or collectively further operable to execute the code to cause the second wireless device to:
generate the full binary coding tree based at least in part on the one or more feedback bits comprising independent and identically distributed bits, and wherein the full binary coding tree is generated in accordance with a probability associated with each bit of the one or more feedback bits; and
generate the pruned binary coding tree based at least in part on the full binary coding tree and in accordance with the one or more conditions for the pruned compression coding configuration.

15. The second wireless device of claim 9, wherein the one or more processors are individually or collectively further operable to execute the code to cause the second wireless device to:
generate the full binary coding tree based at least in part on the one or more feedback bits comprising correlated feedback bits, and wherein the full binary coding tree is generated in accordance with a probability associated with each bit of the one or more feedback bits and in accordance with a correlation factor associated with the one or more feedback bits; and
generate the pruned binary coding tree based at least in part on the full binary coding tree and in accordance with the one or more conditions for the pruned compression coding configuration.

16. The second wireless device of claim 9, wherein in accordance with the one or more conditions for the pruned compression coding configuration, a first node of the one or more nodes of the full binary coding tree is replaced with at least one codeword associated with at least a second node of the one or more nodes of the full binary coding tree to generate the pruned binary coding tree.

17. A method for wireless communications at a first wireless device, comprising:
communicating, with a second wireless device, signaling that indicates one or more conditions for a pruned compression coding configuration, wherein, in accordance with the one or more conditions for the pruned compression coding configuration, one or more nodes of a full binary coding tree are replaced with a plurality of equiprobable bits to generate a pruned binary coding tree;
generating one or more codewords based at least in part on one or more feedback bits in accordance with the pruned binary coding tree; and
transmitting a feedback message to the second wireless device based at least in part on channel encoding the one or more codewords.

18. The method of claim 17, wherein the one or more conditions for the pruned compression coding configuration comprise a pruned binary coding tree depth, a maximum codeword length, a quantity of codeword length groups, a quantity of channel encoding steps, a quantity of channel decoding steps, or any combination thereof.

19. The method of claim 17, wherein, in accordance with the one or more conditions for the pruned compression coding configuration, a first maximum codeword length associated with the pruned binary coding tree is shorter than a second maximum codeword length associated with the full binary coding tree, and
in accordance with the one or more conditions for the pruned compression coding configuration, a first quantity of codeword length groups associated with the pruned binary coding tree is less than a second quantity of codeword length groups associated with the full binary coding tree.

20. The method of claim 17, wherein the pruned compression coding configuration comprises a pruned Huffman coding configuration, and wherein the full binary coding tree and the pruned binary coding tree comprise a full Huffman coding tree and a pruned Huffman coding tree, respectively.

21. The method of claim 17, wherein transmitting the feedback message comprises:
channel encoding a set of bits of the one or more codewords in accordance with one or more lengths of the one or more codewords.

22. The method of claim 17, further comprising:
generating the full binary coding tree based at least in part on the one or more feedback bits comprising independent and identically distributed bits, and wherein the full binary coding tree is generated in accordance with a probability associated with each bit of the one or more feedback bits; and
generating the pruned binary coding tree based at least in part on the full binary coding tree and in accordance with the one or more conditions for the pruned compression coding configuration.

23. The method of claim 17, further comprising:
generating the full binary coding tree based at least in part on the one or more feedback bits comprising correlated feedback bits, and wherein the full binary coding tree is generated in accordance with a probability associated with each bit of the one or more feedback bits and in accordance with a correlation factor associated with the one or more feedback bits; and
generating the pruned binary coding tree based at least in part on the full binary coding tree and in accordance with the one or more conditions for the pruned compression coding configuration.

24. A method for wireless communications at a second wireless device, comprising:
communicating, with a first wireless device, signaling that indicates one or more conditions for a pruned compression coding configuration, wherein, in accordance with the one or more conditions for the pruned compression coding configuration, one or more nodes of a full binary coding tree are replaced with a plurality of equiprobable bits to generate a pruned binary coding tree;
receiving a feedback message comprising one or more encoded codewords; and
decoding the one or more encoded codewords based at least in part on the pruned binary coding tree to obtain one or more feedback bits of the feedback message.

25. The method of claim 24, wherein the one or more conditions for the pruned compression coding configuration comprise a pruned binary coding tree depth, a maximum codeword length, a quantity of codeword length groups, a quantity of channel encoding steps, a quantity of channel decoding steps, or any combination thereof.

26. The method of claim 24, wherein, in accordance with the one or more conditions for the pruned compression coding configuration, a first maximum codeword length associated with the pruned binary coding tree is shorter than a second maximum codeword length associated with the full binary coding tree, and
in accordance with the one or more conditions for the pruned compression coding configuration, a first quantity of codeword length groups associated with the pruned binary coding tree is less than a second quantity of codeword length groups associated with the full binary coding tree.

27. The method of claim 24, wherein the pruned compression coding configuration comprises a pruned Huffman coding configuration, and wherein the full binary coding tree and the pruned binary coding tree comprise a full Huffman coding tree and a pruned Huffman coding tree, respectively.

28. The method of claim 24, wherein channel decoding the one or more encoded codewords comprises:
channel decoding a set of bits of the one or more encoded codewords in accordance with one or more lengths of the one or more encoded codewords.

29. The method of claim 24, further comprising:
generating the full binary coding tree based at least in part on the one or more feedback bits comprising independent and identically distributed bits, and wherein the full binary coding tree is generated in accordance with a probability associated with each bit of the one or more feedback bits; and
generating the pruned binary coding tree based at least in part on the full binary coding tree and in accordance with the one or more conditions for the pruned compression coding configuration.

30. The method of claim 24, further comprising:
generating the full binary coding tree based at least in part on the one or more feedback bits comprising correlated feedback bits, and wherein the full binary coding tree is generated in accordance with a probability associated with each bit of the one or more feedback bits and in accordance with a correlation factor associated with the one or more feedback bits; and
generating the pruned binary coding tree based at least in part on the full binary coding tree and in accordance with the one or more conditions for the pruned compression coding configuration.
